(19) United States
(12) Patent Application Publication
(10) Pub. No.: US 2026/0343783 A1
(43) Pub. Date: Oct. 29, 2026

(54) PROPORTIONAL POWER CONTROL OF SYSTEMS WITHIN A RACK

(71) Applicant: NVIDIA Corporation, Santa Clara, CA (US)

(72) Inventors: Johan van de Groenendaal, Portland, OR (US); Tejvansh Singh Soni, Union City, CA (US); Chad Plummer, Fairfax, CA (US); Jared Huntington, Seattle, WA (US); David Paul Mohr, Houston, TX (US)

(21) Appl. No.: 19/189,833

(22) Filed: Apr. 25, 2025

(51) Int. Cl. H05K 7/14

(52) U.S. Cl. CPC H05K 7/1492; H05K 7/1498

(57) ABSTRACT

A method and system for proportional power control of systems within a server rack, the method including monitoring power draw at at least one power supply at a first frequency, responsive to detecting that a first power draw at a particular time satisfies a power change criterion, determining a proportional power change for the one or more computing devices, transmitting a first power change message including a first indication of the proportional power change via the first low-latency communication network to the one or more computing devices, and causing the one or more computing devices to reduce at least one power consumption based on the first power change message.

### TECHNICAL FIELD

At least one embodiment pertains to data center management. For example, at least one embodiment pertains to proportional power control of systems within a server rack of a data center.

### BACKGROUND

Data centers consume large amounts of power. Data centers often have power overhead (e.g., unused but available power) to avoid black outs, brown outs, or other power-disrupting events that can damage components of the data center. Reducing the power consumed by components of a data center improves the power efficiency of the data center and can reduce the required amount of power overhead.

### BRIEF DESCRIPTION OF DRAWINGS

Various embodiments in accordance with aspects of the disclosure will be described with reference to the drawings, in which:

FIG. 1A illustrates an example system, according to some aspects of the disclosure.

FIG. 1B illustrates an example data base, according to some aspects of the disclosure.

FIG. 2 is a block diagram of an example communication interconnect, according to some aspects of the disclosure.

FIG. 3A illustrates an example system that implements proportional power control of systems within a server rack, according to some aspects of the disclosure.

FIG. 3B illustrates an example power shelf, according to some aspects of the disclosure.

FIG. 3C illustrate an example signal diagram for systems that experience power-loss events.

FIG. 3D illustrates an example signal diagram for systems that experience power-loss events in a proportional power delivery system, according to some aspects of the disclosure.

FIG. 4A is a flow diagram of an example method for proportional power control of systems within a server rack, according to some aspects of the disclosure.

FIG. 4B is an example diagram of a rack architecture in which the method of FIG. 4A can be performed, according to some aspects of the disclosure

FIG. 4C is a flow diagram of an example method for a proportional power control of systems within a server rack, according to some aspects of the disclosure.

FIG. 5 is a flow diagram of an example method for proportional power control of systems within a server rack, according to some aspects of the disclosure.

FIG. 6 is a block diagram illustrating an exemplary computer system, according to some aspects of the disclosure.

FIG. 7 is a block diagram illustrating an electronic device for utilizing a processor, according to some aspects of the disclosure.

FIG. 8 is a block diagram of a processing system, according to some aspects of the disclosure.

FIG. 9 is a block diagram that schematically illustrates a computing system, e.g., a data center or a High-Performance Computing (HPC) cluster, according to some aspects of the disclosure.

FIG. 10 is a block diagram of a computing system having a CPU and a GPU in a single integrated circuit, according to some aspects of the disclosure.

FIG. 11 is a block diagram of a computing system having tensor core GPUs, according to some aspects of the disclosure.

### DETAILED DESCRIPTION

The power requirements for data centers continue to increase. Some data centers may use central processing units (CPUs) to process workloads. However, more and more data centers are using graphics processing units (GPUs), data processing units (DPUs), or the like to process workloads. GPUs and DPUs often have a higher transistor density than CPUs, which results in an increased power draw for GPUs and DPUs in comparison to CPUs. As more GPUs and DPUs are used in data centers, the power variability of the data center can also increase significantly.

Some data centers are organized into multiple server racks. As used herein, a “server rack” refers to a standardized physical framework that houses multiple computing devices (e.g., servers, etc.), networking components (e.g., network switches, etc.), and related hardware and cabling. A server rack can include multiple computing nodes. A s used herein, a “computing node” refers to a component including one or more computing devices and one or more power supplies. As used herein, a “computing device” can include one or more computing components, such as a CPU, a GPU, a DPU, or the like (e.g., respective computing components).

In some data centers, power delivery is managed at the server rack level. In the event of a power excursion (e.g., an input power, or power draw of the server rack exceeds a normal operating condition), the power provided to computing devices of the server rack, including computing components, can be modified. For example, if the power excursion is the result of a drop in available power, the power provided to the computing devices of the server rack can similarly be dropped, causing a reduction in performance (also referred to as “throttling”) of computing components such as a CPU, GPU, DPU, or the like. However, this change in the power delivery to computing components may cause damage to the computing components, interrupt a workload, or otherwise impede the performance of the server rack. For example, a sudden drop in voltage or frequency may cause a brownout, which may result in electrical current spikes as the computing component or related circuitry attempts to continue to draw the same amount of power. In some cases, when a system detects that there is more demand for power than there is available power, the system generates a power break signal to cut off power to one or more components. However, such power break signals can create instability, performance loss, and inefficient power allocation in a data center.

In an attempt to avoid cutting the power delivery and to prevent potential power loss events, the power delivery for the server rack can be overprovisioned. That is, the server rack can be provided with an extra power buffer. For example, a maximum power consumption value can be determined to be 9 kilowatts (KW) for a server rack based on an assumption that every component will operate at 100% capacity. If an additional 1 KW hour is added as an extra power buffer, then the server rack will run at a maximum 90% utilization (e.g., consuming only 90% of available power). When the server rack operates below 100% capacity, the utilization value decreases accordingly.

Aspects of the present disclosure address these and other challenges by providing proportional power control of systems within a server rack. A rack power controller monitors the power draw of a server rack and/or of individual servers at a high frequency (e.g., approximately 100-250 microsecond (μs) intervals with an average window of 0.5-2 microseconds (ms)). In some instances, the power draw can be monitored as a function of the electrical current draw across the rack and/or server. When the rack and/or server power controller detects that the power draw (or electrical current draw) of the server rack and/or server exceeds a predefined threshold criterion, the server rack and/or server sends a message to individual computing components (e.g., CPU, GPU, DPU, etc.) of the server rack and/or server via a low-latency network, such as a controller area network (CAN) bus. The message indicates to each respective computing component to modify power consumption by a certain amount. The power consumption modification amount can be based on multiple factors, including one or more of a number of alternating current (AC) inputs to the server rack, a number of active power supply units (PSUs) (e.g., respective power supply units), a predefined limit for the server rack or data center, or the like. For example, the message can indicate that the power of each respective computing component should be reduced by 10%. Each computing component can implement the power reduction based on the received message. For example, a GPU may lower a clock frequency to reduce the power consumption of the GPU by 10%.

In some instances, the power consumption of each computing component in the server rack can be monitored by the same or another low-latency network that is used to monitor the power consumption of a server rack and/or server. This can allow for even more granular control over power consumption of computing components based on real-time feedback of power consumption values. In some instances, the computing components can have low-latency hardware input that allows for direct hardware connection to the low-latency network. This can allow the rack-connected computing components to be directly controlled by the rack power controller and/or server power controller via the low-latency network. In other instances, an external component (e.g., a controller) receives the message from the low-latency network and provides the message to the computing component in instructions that can be read or processed by the computing component. The computing component receives the instructions from the controller and adjusts its power consumption accordingly. For example, the computing component can inject a proportional analog signal into the current monitoring circuit used by the computing component to actuate the change. In some instances, if the power draw of a particular component is lower than a provisioned power, the power can be increased by sending a message over the low-latency bus indicating that the power may be increased by a certain percentage. The component (e.g., a GPU) can respond by increasing a clock frequency based on the message (and thus increase power draw).

In embodiments, systems and methods for proportional power control of servers and/or individual components of servers are provided. The proportional power control techniques discussed herein ensure that a server rack remains within compliance of a given electrical and power profile, which helps to increase component density (e.g., such as GPU, CPU and/or DPU density) in a datacenter. Additionally, the proportional power control techniques discussed herein ensure that when a power excursion occurs, it is contained within a rack and is not visible to the power distribution network within the datacenter. Additionally, in embodiments, the proportional power control techniques enable computing components (e.g., GPUs, DPUs, CPUs, etc.) to be provisioned to use increased power without impacting the power delivery network of the datacenter.

Advantages of the disclosure include, but are not limited to, an increased efficiency in data center energy consumption, an increased performance-to-power density for the data center, a reduction in damage to computing components, and overall improved workload processing efficiency. Additional advantages include a less strict power control of the power provided to the device can result in an overall improved utilization of the provisioned power by the compute resources for the data center, the rack, and each component of the rack.

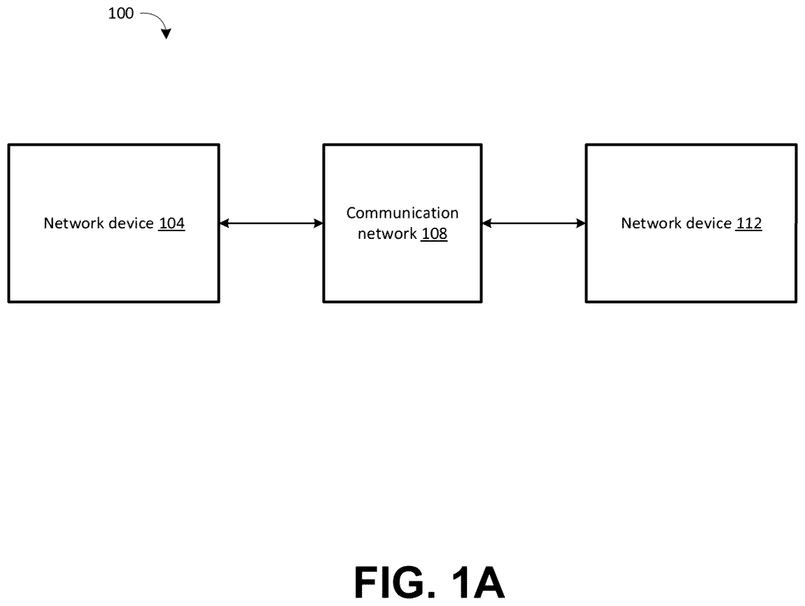

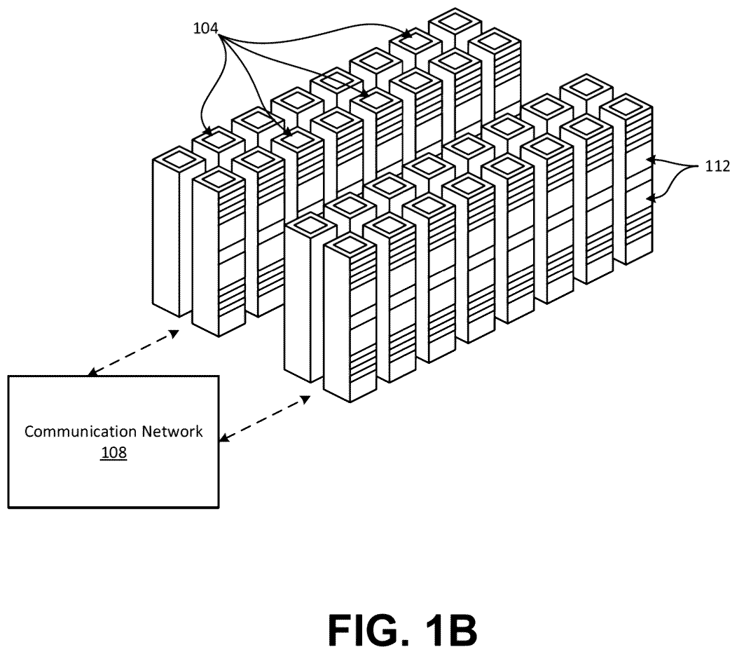

FIG. 1A illustrates a system 100, according to some aspects of the disclosure. The system 100 includes a network device 104, a communication network 108, and a network device 112 (also referred to hereinafter as a “network element”). In at least one example embodiment, network devices 104 and 112 may correspond to a network switch (e.g., an Ethernet switch), a network interface controller (NIC), or any other suitable device used to control the flow of data between devices connected to communication network 108. Each network device 104 and 112 may be connected to one or more of Personal Computer (PC), a laptop, a tablet, a smartphone, a server, a collection of servers, a GPU, or the like. In one specific, but non-limiting example, each network device 104 and 112 includes multiple network switches in a fixed configuration or in a modular configuration. The switches within each layer (e.g., edge layer, aggregation layer, core layer) may be 1 U switches, where “1 U” refers to the industry-standard size for rack-mounted switches and servers. The switches may be electrical switches, optical switches, hybrid electro-optical switches, or any combination thereof. The switches may be implemented with suitable hardware and/or software that enables the routing of signals in the appropriate domain. For example, an electrical switch may include receivers that receive and convert optical signals into electrical signals for routing within the electrical switch. A receiver of an electrical switch may include a transimpedance amplifier (TIA), a photodetector, and a controller which all serve to convert the optical signals into electrical signals. Each electrical switch may further include transmitters that convert electrical signals routed within the electrical switch into optical signals for output to another switch (optical or electrical) within the system. For example, a transmitter of an electrical switch may include a light source, a modulator, and a controller that controls the modulator and light source. In some embodiments, receiver/transmitter pairs may be integrated into a single transceiver. Each electrical switch may also include internal switching circuitry for routing electrical signals within the electrical switch.

In some embodiments, the network device 104 can be a rack in a data center, as illustrated in FIG. 1B. Data centers may include multiple network switches in a particular topology, such as a fat tree topology, a slim fly topology, or indirect network topology (e.g. folded-Clos or a dragonfly topology), and/or the like. The specifications and makeup of the network switches in the topology affects the overall network performance (e.g., bandwidth capability) of the data center.

High performance computing clusters, and/or the like are often formed of various computing components or networked devices, and communication networks formed of electrical and/or optical devices may be used to enable communication between the networked devices forming these implementations.

For example, the network device 104 may be a centralized facility designed to house computing resources and related components. The network device 104 may operate to support the infrastructure required for advanced computational tasks, for efficient, secure, and reliable operations. The network device 104 may include the building and structural components, including power supplies, cooling systems, fire suppression systems, and physical security measures that are configured to maintain optimal operating conditions and/or protect the equipment from environmental hazards and unauthorized access. An example network device 104 may include high-performance servers or compute nodes, often arranged in racks, such as those illustrated in FIG. 1B, and connected through high-speed networks as described herein. These servers may include processors (e.g., central processing units (CPUs), graphics processing units (GPUs), data processing units (DPUs) and/or the like), memory (e.g., RAM), and storage solutions (e.g., hard disk drives (HDDs), solid state drives (SSDs), and/or the like. The hardware configuration may be designed for parallel processing and high throughput, catering to the demands of high-performance computing (HPC) applications.

The network device 104 may include high-speed network equipment, such as network switches, routers, firewalls, and/or the like to facilitate fast and secure data transmission within the network device 104 (e.g., between the servers or compute nodes) and between external networks. The network device 104 may facilitate communication between servers or compute nodes through a network topology that ensures efficient data exchange, minimizes latency, and maximizes bandwidth. The network topology may dictate how various network devices, such as switches and routers, are interconnected for data flow. By implementing an effective network topology, the network device 104 may support high-performance computing tasks. Examples of various network topologies may include hierarchical networking topologies such as the fat tree topology, Slim Fly topology, Dragonfly topology, and/or the like.

Examples of the communication network 108 that may be used to connect the network devices 104 and 112 include an Internet Protocol (IP) network, an Ethernet network, an InfiniBand (IB) network, a Fibre Channel network, an NVLINK fabric, the Internet, a cellular communication network, a wireless communication network, combinations thereof (E.g., Fibre Channel over Ethernet), variants thereof, and/or the like. In one specific, but non-limiting example, the communication network 108 is a network that enables communication between the network devices 104 and 112 using Ethernet technology.

Each network device 104 and 112 may be connected to a communication network 108 that has multiple network switching layers. The number of network devices 104 and 112 that may be connected to the communication network 108 can be increased by increasing the radix of the communication network 108. The radix of the communication network 108 is increased by increasing the radix of each network layer in the communication network 108. The radix of each network layer is increased using optical shuffle boxes that implement wavelength division multiplexing as described herein below in embodiments. The communication network 108 can include one or more electrical switches, optical switches, electrooptical transceivers, or the like, as described herein below.

The communication network 108 may communicably couple the network device 104 with network device 112 and other external devices for data exchange and connectivity. Examples of the communication network 108 may include an Internet Protocol (IP) network, an Ethernet network, an InfiniBand (IB) network, a Fibre Channel network, an NVLINK fabric, the Internet, a cellular communication network, a wireless communication network, combinations thereof (e.g., Fibre Channel over Ethernet), variants thereof, and/or the like. The ability of the communication network 108 to incorporate multiple network types and configurations may allow the network device 104 to adapt to diverse application needs, from general data communication to specialized HPC tasks. As described herein, the communication network 108 may leverage various optical components to establish communication links (e.g., communicably couple) between components in the computing system 100. As such, the communication network 108 may include various optical devices, transceivers, modules, and/or the like that are configured to generate optical data signals (e.g., provide optical transmitter functionality) and/or receive optical data signals (e.g., provide optical receiver functionality).

The network device 112 may include a variety of computing devices capable of transmitting and receiving signals over the communication network 108. The network device 112 may range from personal computing devices to complex server configurations. Examples include Personal Computers (PCs), laptops, tablets, smartphones, and servers. The network device 112 may facilitate user interactions with the network device 104, allowing for data input, retrieval, and processing from remote locations. In addition to individual computing devices, the network device 112 may also include collections of servers or additional data centers. For instance, these could be other data centers similar to or the same as network device 104. Such an interconnection may allow for the formation of a distributed computing environment for improved redundancy, load balancing, and disaster recovery capabilities. By linking multiple data centers, the system 100 may leverage geographically dispersed resources, optimizing performance and ensuring high availability.

As described herein, the network device 104 and/or the network device 112 may include storage devices and processing circuitry for executing computing tasks, such as controlling the flow of data internally and over the communication network 108. The processing circuitry may include software, hardware, or a combination thereof. For example, the processing circuitry may include a memory containing executable instructions and a processor (e.g., a microprocessor) that executes these instructions. The memory may correspond to any suitable type of memory device or collection of memory devices configured to store instructions. Non-limiting examples of suitable memory devices include Flash memory, Random Access Memory (RAM), Read Only Memory (ROM), variants thereof, combinations thereof, or similar technologies. In specific embodiments, the memory and processor may be integrated into a common device, such as a microprocessor with integrated memory. Additionally, or alternatively, the processing circuitry may comprise hardware components, such as an application-specific integrated circuit (A SIC). Other non-limiting examples of processing circuitry include Integrated Circuit (IC) chips, CPUs, GPUs, microprocessors, Field Programmable Gate Arrays (FPGA s), collections of logic gates or transistors, resistors, capacitors, inductors, and diodes. Some or all of the processing circuitry may be provided on a Printed Circuit Board (PCB) or a collection of PCBs. It should be appreciated that any appropriate type of electrical component or collection of electrical components may be suitable for inclusion in the processing circuitry.

In addition, although not explicitly shown, the present disclosure contemplates that the network device 104 and network device 112 may include one or more communication interfaces for facilitating wired and/or wireless communication between one another and other unillustrated elements of the system 100. These communication interfaces may include a variety of technologies, including but not limited to Ethernet ports, fiber optic connections, Wi-Fi® transceivers, Bluetooth® modules, and cellular communication modules for integration and interoperability among the various components within the system 100.

Furthermore, the present disclosure contemplates that the system 100 may include additional components and functionalities. For example, the network architecture may include, without limitation, additional processing units, specialized accelerators (such as Tensor Processing Units or TPUs), enhanced security modules, and redundant power supplies. The inclusion of these elements may be intended to ensure that the system 100 is robust, scalable, and capable of meeting diverse operational requirements. Any variations, modifications, or adaptations of the described elements that fall within the spirit and scope of the disclosure are considered to be encompassed by the present disclosure. This includes any combinations, sub-combinations, or enhancements of the various described elements to achieve improved performance, reliability, and efficiency in the system 100.

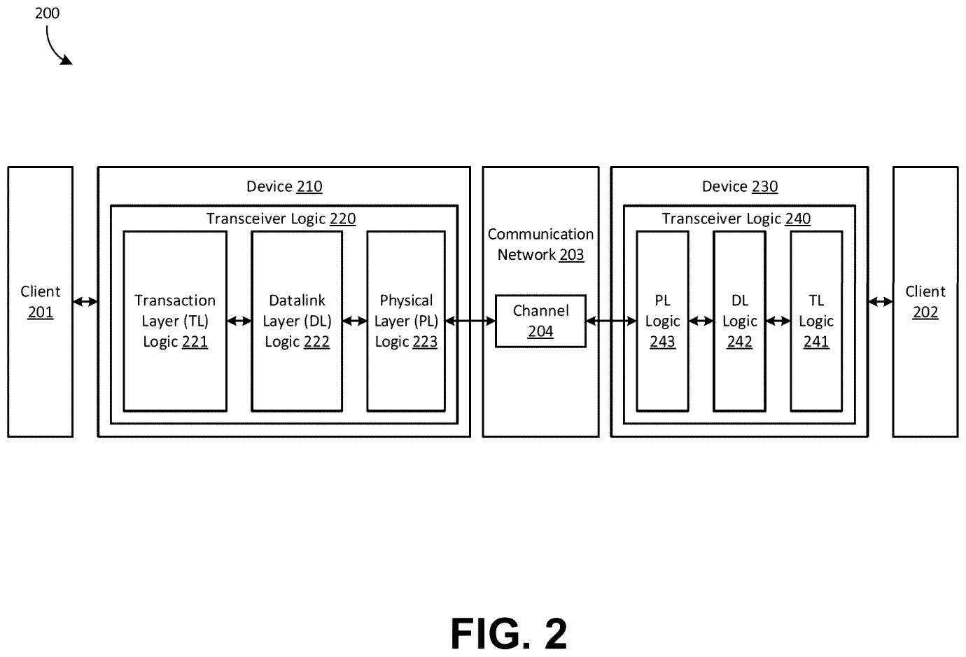

FIG. 2 is an example block diagram of a communication interconnect 200, according to some aspects of the disclosure. The communication interconnect 200 may be used to connect two or more components of the data center described above with reference to FIG. 1A-1B.

The communication interconnect 200 includes a client 201 coupled to a device 210 and a client 202 coupled to a device 230. The device 210 and the device 230 are coupled together via the communication network 203 to transmit and receive data. In some embodiments, the transmitted and received data is in a data frame(s). Device 210 includes transaction layer (TL) logic 221, datalink layer (DL) logic 222, and physical layer (PL) logic 223. The device 230 similarly includes TL logic 241, DL logic 242, and PL logic 243. The function and operation of the device 210 described herein similarly apply to the function and operation of the device 230 unless explicitly noted.

In some embodiments, the client 201 is an integrated circuit of a Personal Computer (PC), a laptop, a tablet, a smartphone, a server, a collection of servers, or the like. In some embodiments, the client 201 may correspond to any appropriate type of device that communicates with other devices also connected to a common type of communication network 203.

The device 210 can be an integrated circuit of a graphics processing unit (GPU), a switch (e.g., a high-speed network switch), a network adapter, a central processing unit (CPU), a data processing unit (DPU), a neural processing unit (NPU), an application-specific integrated circuit (ASIC), a field programmable gate array (FPGA), a network interface card (NIC), or the like. The device 210 can be implemented in components in clients referred to as machines, computers, servers, network devices, or the like (e.g., client 201).

The communication interconnect 200 allows the client 201 to communicate with the client 202 via the communication network 203 and devices 210, 230, respectively. The client 201 can cause the device 210 to transmit and receive data with the client 202 (or another client coupled to the communication network 203 via another respective device) via a channel 204. Similarly, the client 202 can cause the device 230 to transmit and receive data across the communication network 203 via the channel 204.

Examples of the communication network 203 that may be used to connect the device 210 and device 230 include wires, conductive traces, bumps, terminals, optical fibers, or the like. In other embodiments, the communication network 203 can be a Peripheral Component Interconnect Express (PCIe) interconnect. PCIe is a high-speed interface standard used to connect various hardware components. It can be an interconnect for devices such as graphics cards (GPUs), solid-state drives (SSDs), network cards, and other peripherals. PCIe offers a scalable, high-speed, and point-to-point connection between devices, including CPUs, GPUs, memory, and the like. In other embodiments, the communication network 203 can be a high-speed interconnect, such as an interconnect that deploys the NV LINK technology. The NVLINK interconnect can be a GPU-GPU interconnect used between GPUs, a CPU-GPU interconnect between GPUs and CPUs, or an interconnect used between other devices. NVLINK offers a higher bandwidth and lower latency than traditional PCIe connections, which are typically used in computing hardware. NVLINK is especially useful in scenarios that require massive parallel processing, such as artificial intelligence (AI), machine learning, deep learning, high-performance computing (HPC), and data analytics. For example, in NVIDIA's DGX systems and high-end gaming or AI workstations, NVLINK helps GPUs exchange data at speeds that are necessary for demanding tasks like real-time ray tracing or training neural networks. In one specific, but non-limiting example, the communication network 203 is a network that enables data transmission between the device 210 and device 230 using data signals (e.g., digital, optical, wireless signals), clock signals, or both. The embodiments described herein can be utilized in a system with a high-speed, scalable switch, such as a switch using the NV Switch technology. NV Switch is a high-speed, scalable switch developed by NVIDIA that facilitates data communication between multiple GPUs in a system, allowing them to work together more efficiently by providing high-bandwidth, low-latency interconnections. The NV Switch serves as a central hub or high-bandwidth fabric that interconnects all the GPUs in a system, enabling each GPU to communicate with every other GPU quickly and efficiently. The NV Switch can be coupled between other types of devices, such as CPUs, accelerators, memory, or the like. The NV Switch can be used for tasks requiring intense computation and collaboration between multiple GPUs, such as AI model training, scientific simulations, and large-scale data processing. The embodiments described herein can be used in a high-performance computing system, such as a computing system modeled after NVIDIA's DGX systems, which are designed specifically for artificial intelligence (AI), deep learning, and high-performance computing (HPC) workloads. DGX systems are optimized for large-scale GPU computation and parallel processing, integrating multiple GPUs, high-bandwidth interconnects, and software frameworks tailored for AI and HPC tasks. In at least one embodiment, a system for high-speed network communication includes a processing unit, a network interface comprising a receiver or transceiver with the control logic, as described herein.

Other examples for the communication network 203 can include other chip-to-chip or die-to-die interconnects, such as GRS (Ground-Referenced Signaling), LPI (low power interface) or LLI (low latency interface).

In embodiments, the device 210 can interface with the client 201 to transmit and receive data over a two-way communication stream (e.g., channel 204 of the communication network 203). The channel 204 can be PCIe, NVLINK, Ethernet, InfiniBand, Ground Reference Signal (GRS), C2C, D2D, or the like. As illustrated, device 210 is single device which includes transceiver logic 220 (and device 230 respectively includes the transceiver logic 240). The transceiver logic 220 can be used to send and receive data signals via the communication network 203. In some embodiments, the device 210 can include a transceiver device, transmitter device, or receiver device, which may include some or all of the transceiver logic 220.

The transceiver logic 220 includes suitable software, firmware, and/or hardware for receiving digital data from a source (e.g., client 201) and outputting data signals according to the digital data for transmission over the communication network 203. In some embodiments, the transceiver logic 220 can generate and transmit frames including data from the client 201 over the communication network 203 to the device 230. For example, the transceiver logic 220 can generate and transmit frames across the channel 204 to the device 230.

The transceiver logic 220 also includes suitable software, firmware, and/or hardware for receiving digital data from a device over the communication network 203 and outputting digital data for further processing by a recipient (e.g., client 201). For example, the transceiver logic 220 may include components for receiving processing signals to extract the data for storing in a memory. In some embodiments, the transceiver logic 220 can receive and process frames including data from the client 202 over the communication network 203 from another device 230. For example, the transceiver logic 220 can receive and process frames including data from the client 202 across the channel 204 from the device 230. In some embodiments, the transceiver logic 220 receives an incoming signal and samples the incoming signal to generate samples, such as using an analog-to-digital converter (ADC). The ADC can be controlled by a clock-recovery circuit (or clock recovery block) in a closed-loop tracking scheme. The clock-recovery circuit can include a controlled oscillator, such as a voltage-controlled oscillator (VCO) or a digitally-controlled oscillator (DCO) that controls the sampling of the subsequent data by the ADC.

The transceiver logic 220 includes multiple processing elements, such as one or more of transaction layer (TL) logic 221, datalink layer (DL) logic 222, or physical layer (PL) logic 223, as illustrated. Similarly, the transceiver logic 240 of the device 230 can include corresponding processing elements such as TL logic 241, DL logic 242, and PL logic 243, as illustrated. The transceiver logic 220 or selected elements of the device 210 may take the form of a pluggable card or respective controller for the device 210. For example, the transceiver logic 220 or selected elements of the device 210 may be implemented on a network interface card (NIC). In an alternative example, the functions of the transceiver logic 220 can be performed by separate devices of the communication interconnect 200. For example, a first device can include the transaction layer logic 221, a second device can include the datalink layer logic 222, and a third device can include the physical layer logic 223.

The transaction layer logic 221 can interface directly with the client 201. The transaction layer logic 221 can receive data from the client (e.g., “client data”) that is to be transmitted across the communication network 203. In some embodiments, the transaction layer logic 221 can divide the data received from the client 201 into predetermined quantities. For example, data received from the client 201 may be several kilobytes of data, and the transaction layer logic 221 can break the data down into evenly sized chunks of one byte each. Additional predetermined “chunk” sizes or data quantities are considered.

The datalink layer logic 222 can receive the predetermined quantity of data from the transaction layer logic 221 and package the received data into a frame to be transmitted across the communication network 203. In some embodiments, a frame of data includes the quantity of data (e.g., one byte of data).

The physical layer logic 223 interfaces directly with the communication network 203 to transmit the frame across the communication network 203 to the device 230, where the PL logic 243 receives the frame and provides the received frame to the DL logic 242. The DL logic 242 extracts the data from the received frame and provides the extracted data to the TL logic 241. The TL logic 241 can provide the extracted data to the client 202. Similarly, data can be sent from TL logic 241 to DL logic 242 for packaging the data into a frame. The frame can be sent via the physical logic 242 of the device 230 and received via the physical layer logic 223 of the device 210. The physical layer logic 223 provides the received frame to the datalink layer logic 222, which extracts the data from the received frame. The transaction layer logic 221 obtains the extracted data from the datalink layer logic 222 and provides the extracted data to the client 201. In some embodiments, the TL logic 241 assembles multiple sets of extracted data to provide to the client 202 simultaneously.

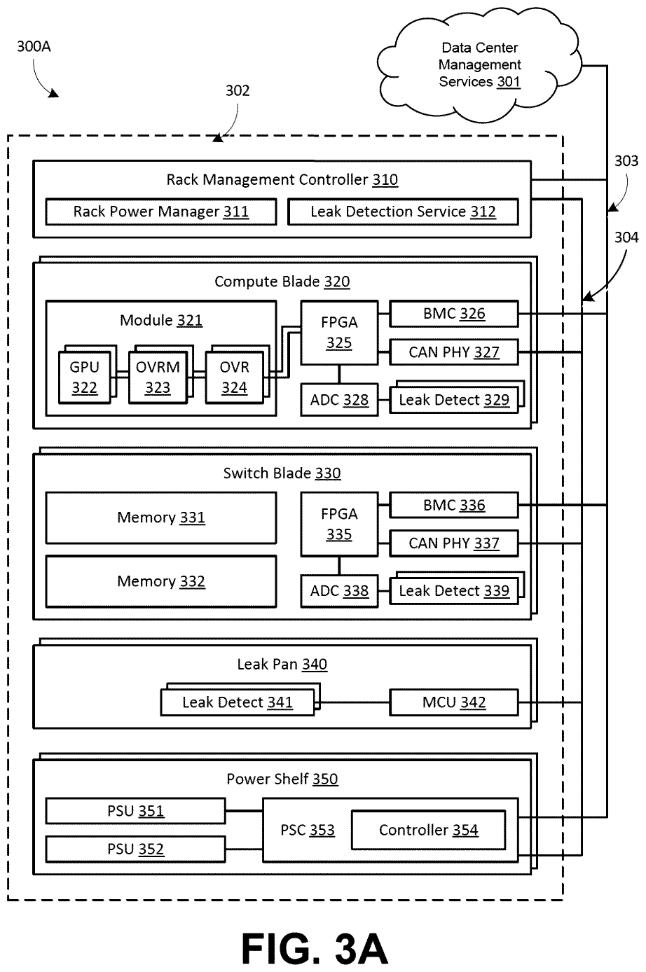

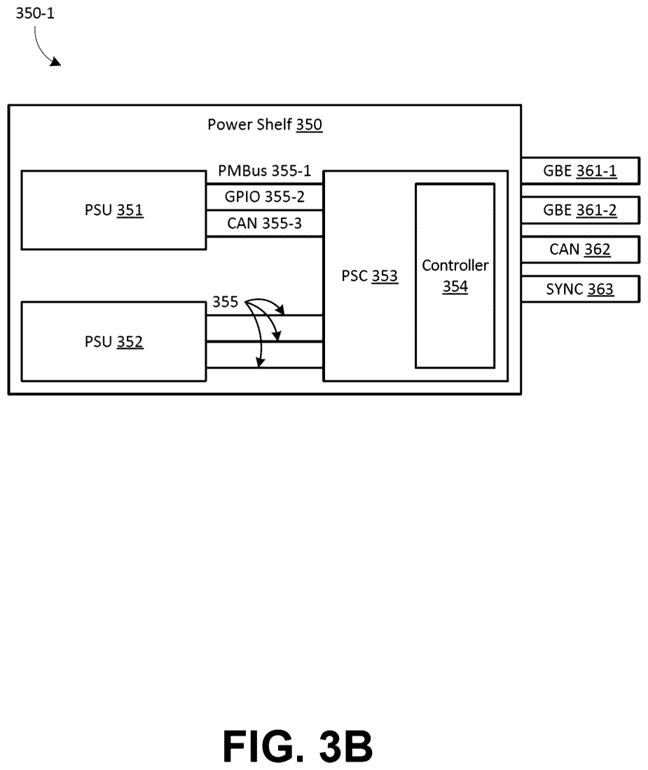

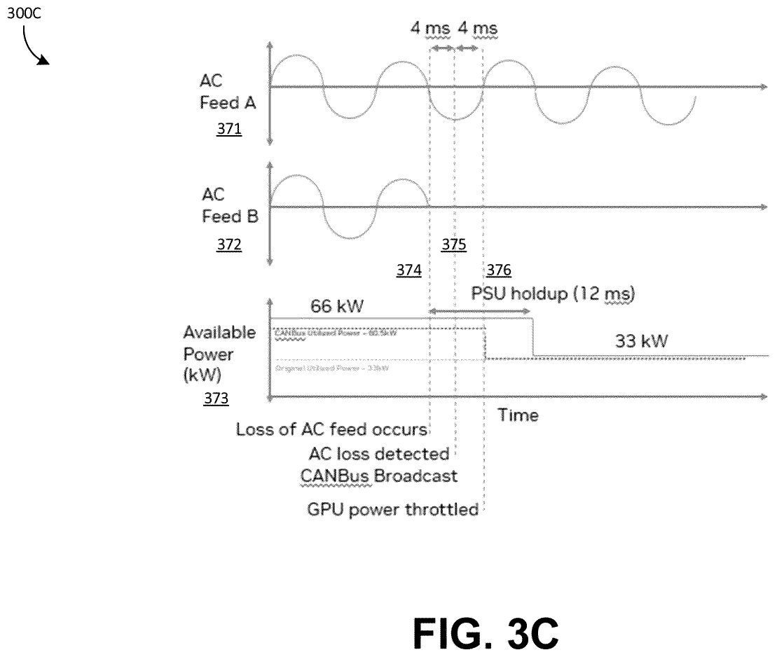

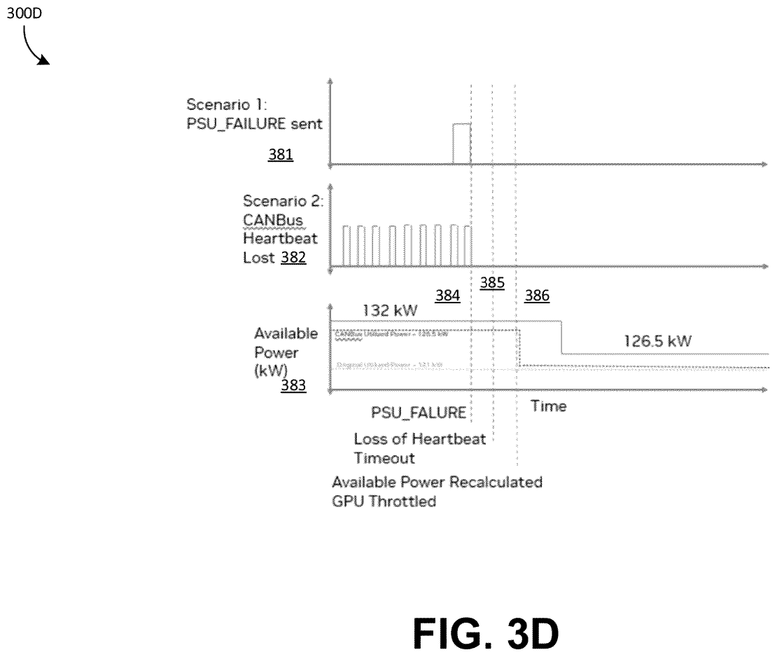

FIG. 3A illustrates an example system 300A that implements proportional power control of systems and/or methods within a server rack, according to some aspects of the disclosure. The system diagram illustrates data center management services 301 that are connected to various components of a server rack 302. The server rack 302 includes a rack management controller 310, one or more compute blades 320, one or more switch blades 330, one or more leak pans 340, and one or more power shelves 350. While only one server rack 302 is illustrated and described herein, a data center can include multiple server racks 302. In some embodiments, the data center management services 301 are hosted off-site. That is, the racks 302 may receive instructions from the data center management services 301 that is not at the same location as the racks 302. In embodiments, server rack 302 corresponds to a network device 104 of FIGS. 1A-1B.

A rack management controller 310 can be a centralized hardware or software system that monitors and manages power, cooling, and environmental conditions within a server rack. In some embodiments, the rack management controller 310 provides remote access, automation, and alerting capabilities to optimize data center efficiency and ensure operational reliability.

A compute blade 320 can be a modular server housed within a blade enclosure (e.g., design form factor), designed to provide processing power for data center workloads. In some embodiments, the compute blade 320 shares power, cooling, and networking resources with other blades in the same chassis, enabling high-density, scalable computing.

A switch blade 330 can be a modular network switch designed to be installed in a blade enclosure (e.g., design form factor), that provides connectivity between compute blades and external networks. In some embodiments, the switch blade 330 consolidates networking within the chassis, reducing cabling and improving data transfer efficiency in high-density computing environments (e.g., a data center). In some embodiments, like the compute blade 320, the switch blade 330 shares power, cooling and/or networking resources with other blades in the same chassis.

A power shelf 350 can be a modular power distribution unit that supplies and manages power for multiple servers and devices (e.g., compute blade(s) 320, switch blade(s) 330) within a data center rack (e.g., the same chassis). In some embodiments, the power shelf 350 consolidates power conversion and distribution, improving efficiency, redundancy, and scalability in high-density computing environments.

A network connection 303 can connect the rack management controller 310, compute blade 320, switch blade 330, and power shelf 350 to the data center management services 301. The network connection 303 allows each connected component of the server rack 302 to communicate with each other, and/or with the data center management services 301. The network connection 303 can be enabled using physical connections, such as ethernet or fiber connections, or wirelessly using Wireless Fidelity (Wi-Fi) connections or radio signals. The network connection 303 allows each component of the server rack 302 to exchange information, coordinate operation, or the like. In some embodiments, the network connection 303 can be used by the data center management services 301 to collect telemetry data from each component of the server rack 302. For example, the network connection 303 may be used to collect power consumption values, workload performance statistics, or the like. In some embodiments, this collected telemetry data can be provided to the rack management controller 310.

A low-latency connection 304, such as a controller area network (CAN) bus, RS 485 network, 10Base-T1S network, low-latency ethernet network, or the like, can connect the rack management controller 310, compute blade 320, switch blade 330, leak pan 340, and power shelf 350. In some embodiments, the low-latency connection 304 supports one or more of broadcast, multicast, or unicast operations. The low-latency connection 304 prioritizes rapid transfer of short messages. For example, data packets can be relatively small, and messages can be prioritized for transmission based on the sending device or the receiving device. In some embodiments, messages can be flagged with a higher importance that causes the transmission of these messages to be prioritized. In some embodiments, the low-latency connection 304 operates without a central controller. In some embodiments, the low-latency connection 304 is implemented using the telecommunications industry association (TIA)/electronic industries alliance (EIA) 485 standard (i.e., TIA/EIA-485).

In some embodiments, the latency requirement for the low-latency connection define the time between when a rack power management controller 310 makes a determination and the time a control action is received at the nodes. For practical purposes, the latency value shall include the end-to-end path to a node level power controller (such as the device generating the power control signal to the GPU). In some embodiments, this may include individual messages as well as broadcast.

For example, the rack management controller 310 can implement a control loop that makes a decision every 1 millisecond (ms). For that decision to be made every 1 ms, the latency of the inputs can be defined as:

a. The control loop can perform 10 samples per metric. This implies that the slowest sample rate is 100 microseconds (μs).

b. If the control loop requires more than 1 metric, the constraints become more complicated. In addition to meeting the sampling rate, there may be a maximum delta between samples, such as <50 μs.

c. Actuation latency can be a measurement of the duration of time between when a decision is made, and when the action is initiated. For example, when adjusting power on the GPU, all adjustments should take place within 100 μs of the decision to take an action.

The various latencies described, collectively, define how each entity in the path needs to be behave and what the requirements are. This can include choice of firmware versus RTL, BUS technology choices, etc.

TABLE 1
Examples of Latency Requirements

| Area | Requirement | Min | Max | | Nominal | |
|---|---|---|---|---|---|---|
| CAN | AC Loss | | 12 | ms | 10 | ms |
| CAN | PWR Change Down | <100 us | 100 | us | 100 | us |
| CAN | PWR Change Up | <100 us | 100 | us | 100 | us |
| CAN | Leak Detect | | 10 | s | 1 | s |
| CAN | Heartbeat | | 120 | s | 60 | s |
| PSC | ISENSE | <100 us | 100 | us | <100 | us |
| | Sampling Rate | | | | | |
| PSC | Telemetry Rate | | 1 | ms | 500 | us |
| Compliance PID | Policy Evaluation | | 1 | ms | <1 | ms |

In some embodiments, the actions that are taken (i.e. driving the Messaging to End Points) can be rules based to prevent making unnecessary changes to the system 300A.

In some embodiments, changes to power budgets are handled with respect to direction. That is, there may be different constraints to increasing a power budget than to decreasing a power budget. For example, and in some embodiments, the time constants for a change to reduce a power budget may have a lower latency requirement than a time constraint to increase a power budget.

In some embodiments, decreasing the power budget involves determining a new setpoint for the power shelf 350. The new setpoint for the power shelf 350 can be set based on a new budget and any power actions that were taken. For example, the minimum of the set of (PBdyn, PBmax). In some embodiments, PBdyn (“dynamic power budget”) does change based on the change in power budget. That is, PBDyn=PBDyn-PBmax(old)−PBMax(new) (“maximum power budget”).

The setpoint will be adjusted accordingly and communicated to the systems in the rack. In some embodiments, there are multiple modes to be considered when decreasing the overall power budget for the system, including for example, (i) per virtual cluster budget, (ii) per system cluster budget, and (iii) total rack budget.

In some embodiments, increasing the power budget similarly involves determining a new set point for the power shelf 350. In some embodiments, the setpoint can be the minimum of the set of (PBdyn, PBmax). It should be noted that PBdyn does change based on this new calculation. That is, PBDyn=PBDyn+PBmax(new)−PBMax(old).

In some embodiments, when a power violation occurs, the setpoint to the rack management controller 310 is adjusted to a new value, where: SetPoint=PLDyn−Pstep. As used herein, Pstep refers to a value by which the power is changed up or down (e.g., incremented or decremented). In some embodiments, the value of Pstep is represented as a percentage. For example, given a device with a maximum power value of 1000 watts, a Pstep may be 10%, or 100 watts.

Pstep is the amount to reduce by. It should be noted that PStep may be non-linear in that if the system is not brought into compliance within a given time window, that more aggressive action is required. The rate of change (e.g., Pstep) depends on the duration for which a given threshold is exceeded. In some embodiments, a smaller Pstep value can be used. When a smaller Pstep value is used, messages can be sent out via the low-latency connection 304 more frequently. In some embodiments, the Pstep value (e.g., the percentage of the maximum power) is based on how quickly the programmed control loop can react to a change in power. The Pstep value can be selected to maintain stability of the loop. For example, if the Pstep value is too large, voltage droop may occur. In another example, if the Pstep value is too small, the rack may not return to a compliant power state within a threshold timeframe.

In some embodiments, if action was taken to reduce power, once the system falls below PLx, the power may be gradually increased to reach it setpoint. As used herein, “PLx” refers to a target limit that is a functional minimum of the set of (provisioned power, available power, or a predefined power limit). Available power can be based on a quantity of power supply units (PSUs) that are powered on. In some embodiments, the predefined power limit can be based on, or defined by, a particular workload, customer, or entity that determines a particular power (e.g., an “optimal power”) given the particular conditions or constraints (e.g., the workload, customer priorities, etc.). In some embodiments, this naturally occurs by design of the PID. In some embodiments that support a dynamic power budget, the unused power budget of a system can be allocated to another system, rendering the PID more responsive.

In some embodiments, if an AC Power Loss is detected, this event overrides all other actions and will send an AC power Loss message to systems. Systems are expected to drop power to the Power break TGP.

In some embodiments, if a a partial AC Power Loss is detected, this will be seen as a power violation. Since it is an AC Partial Loss, the setpoint in the PID can be set to a percentage of the current set point. For example, given two power feeds and one power feed fails, the set point it is 50% of the current power. In some embodiments, the power step size (e.g., how much the power changes over a certain period of time) can be proportional to the amount of power lost. That is, if more power is lost (e.g., a larger partial AC power loss) the power step size can be larger, and if less power is lost (e.g., a smaller partial AC power loss) the power step size can be smaller.

The rack management controller 310 includes a rack power manager 311 and a leak detection service 312 in some embodiments. The rack power manager 311 monitors (i) the power coming into the server rack 302, and (ii) the power consumption of the server rack 302. In some embodiments, the rack power manager 311 monitors the power draw of the server rack 302. That is, the rack power manager 311 can be configured to monitor power draw of the server rack 302. In some embodiments, the rack power manager 311 monitors the power draw of the server rack 302 based on a measured electrical current draw for the server rack 302. In some embodiments, the rack power manager 311 can receive instructions from the data center management services 301 indicating how much power is to be allocated to each server rack 302 of a data center (or to a particular server rack). The rack power manager 311 can cause the power shelf 350 to provide the allocated power to the server rack 302. In some embodiments, the rack power manager 311 can determine how much power to provide to a computing component of the compute blade 320 of the server rack 302 based on the instructions from the data center management services 301.

In some embodiments, the rack power manager 311 monitors the current draw across the rack at a high frequency (microseconds) using a PID like controller. The PID controller can monitor the current draw against a policy that defines the maximum power draw. The policy can be derived from multiple inputs including: The number of AC Feeds, number of PSU active, as well as the limit defined by the datacenter operator. When a threshold is exceeded, a proportional percentage drop is sent over a multidrop low-latency connection 304 (e.g. CAN). In some embodiments, when the power falls below a lower limit, a proportional percentage increase is sent over the low-latency connection 304.

In some embodiments, the choice of algorithms is dependent on the configuration of the rack. For example, racks that include energy storage devices may have slower response times as compared to a rack that does not. The proportional control algorithm is based on balancing a number of factors, particularly defining the proportional step size to prevent large and sudden discharge or inrush events, while meeting the time-constants of the power delivery capabilities in the rack and minimizing the overall performance impact.

In some embodiments, to manage the power consumption of computing components of the server rack 302, the rack power manager 311 can send a message to the computing components via the low-latency connection 304. In some embodiments, this message can be received at a host device (e.g., the compute blade 320). A driver for the computing component can process the message from the rack power manager 311 and convert the message into firmware instructions (or the like) that cause the hardware of the computing component to increase or reduce power consumption. In alternative embodiments, the computing component includes a physical low-latency communication port. The rack power manager 311 can send instructions directly to the computing component that cause the hardware of the computing component to increase or decrease power consumption. In this way, latency can be reduced even further, and each computing component may be directly controlled by the rack power manager 311.

Computing elements, such as CPUs, GPUs, DPUs, and other semiconductor devices of the compute blade 320 can have optimal power efficiencies based on a design, construction, operating environment, or the like. That is, performance can increase steadily as more power is provided to the computing component, up to a certain power threshold. After the certain power threshold, the amount of additional performance per each additional power unit begins to drop significantly. The rack power manager 311, in connection with the power shelf 350, can manage the power delivery to each computing component in the server rack 302 (e.g., of the compute blade 320) to optimize power delivery to each of the computing components. In some embodiments, the rack power manager 311 can also manage the power delivery to networking elements in the server rack 302 (e.g., network switches in the switch blade 330).

In some embodiments, the rack power manager 311 can determine how much power to provide to a computing component of the compute blade 320 or to all of the computing components of the compute blade 320 based on one or more measurements of power consumption, or performance of the computing component (or all computing components of the blade 320). For example, the rack power manager 311 can detect an amount of power consumed by a particular computing component over a set duration. In another example, the rack power manager 311 can detect a number of calculations (or the like) performed by the particular computing component over a set duration. The rack power manager 311 can determine a power-to-performance ratio based on the power consumed and number of calculations performed over a set duration. In some embodiments, if the power-to-performance ratio exceeds a set threshold, the rack power manager 311 can reduce the power provided to the computing component of the compute blade 320. It can be appreciated that a compute blade 320 can include multiple compute elements as is further described below, and that the rack power manager 311 can perform these and similar determinations for each compute element, each group of compute elements, or each type of compute element. In some embodiments, the power consumption values and/or performance metrics can be collected via the network connection 303 (e.g., as telemetry data). In alternative embodiments the power consumption values and/or performance metrics can be collected via the low-latency connection 304.

In some embodiments, the rack power manager 311 can detect a loss of power (e.g., a power supply unit (PSU) failure, PSU firmware update, PSU removal, etc.). In such embodiments, the rack power manager 311 can reduce the power consumption of some or all computing components of the server rack 302 using the low-latency connection 304, as described above. For example, the rack power manager 311 can send a message to a host device (e.g., the compute blade 320) which converts the message (via a driver for the computing component) into instructions for the computing component that cause the hardware of the computing component to decrease power consumption. Such messages may be sent to each of the computing components on a server blade in embodiments. In another example, the rack power manager 311 can send a message directly to the computing component via a hardware low-latency connection that causes the hardware of the computing component to decrease power consumption. In some embodiments, the rack power manager 311 can detect an overcurrent fault. In such embodiments, the rack power manager 311 may send a message to the server rack or to the computing components of the server rack 302 to maintain or reduce power consumption. In some embodiments, the rack power manager 311 can detect a low electrical current fault (e.g., a brownout). In such embodiments, the rack power manager 311 may send a message to the server rack 302 or to the computing components of the server rack 302 to maintain or reduce power consumption.

Leak detection, as performed by the leak detection services 312, is used to detect environmental anomalies, such as increases in humidity, moisture, the presence of condensation or standing liquid, or the like. The leak detection service 312 can be connected to various environmental sensors throughout the server rack 302 (not illustrated). When an environmental anomaly, such as a leak, occurs, a rapid response can significantly reduce the impact of the leak on the components of the server rack 302. To this end, in some embodiments the leak detection service 312 can connect to the environmental sensors via the low latency connection 304, as described above.

In embodiments, the compute blade 320 includes a module 321, an field programmable gate array (FPGA) 325, a baseboard management controller (BMC) 326, a CAN physical layer (PHY) component 327, an analog-to-digital converter (ADC) 328, and one or more leak detectors 329.

The module 321 include one or more GPUs 322, one or more overvoltage regulator modules (OVRMs) 323, and/or one or more overvoltage regulators (OVRs) 324. As used herein, an overvoltage regulator module (OVRM) takes stabilized voltage as an input to provide a precise, clean (e.g., consistent) voltage output for sensitive computing components, such as GPU 322. As used herein, an over voltage regulator (OVR) receives an input voltage and produces an output voltages within a certain range of voltages. In some embodiments, if the OVR is unable to produce a voltage within the certain range of voltages based on the input voltage, the OVR may cause the input voltage to physically disconnect from the output voltage (e.g., via a switch, a fuse, or the like). As illustrated, the GPU 322 can receive power via the OVRM 323, which in turn receives power from the OVR 324. In some embodiments, the OVR 324 receives one or more signals from the FPGA 325. Based on the signal from the FPGA 325, the OVR 324 can change the output voltage that is provided to the GPU 322 via the OVRM 323. In some embodiments, the signal provided by the FPGA is a pulse-width modulation (PWM) signal.

The FPGA 325 can allow the components of the compute blade 320 to interface and communicate with each other. The BMC 326 can receive instructions from the rack management controller 310 and/or the data management services 301 and communicate these instructions to other components of the compute blade 320 via the FPGA 325. In some embodiments, the FPGA 325 can allow the compute blade 320 to collect sensor data from leak detectors 329. The leak detectors 329 can collect moisture data, which is converted by the ADC 328 into a digital signal. The FPGA 325 can provide the digitized leak detect signal to the BMC 326.

In some embodiments, the BMC 326 is connected to the rack management controller 310 via the network connection 303. In some embodiments, the BMC 326 is connected to the data center management services 301 via the network connection 303. In some embodiments, the BMC 326 enables remote monitoring and management of the compute blade 320. The BMC 326 can operate independent from the main operating system and regardless of the power state of the compute blade 320 (e.g., whether powered on or off). The BMC 326 allows the data center management services 301 to configure, troubleshoot, modify, etc., the compute blade 320. In some embodiments, the BMC 326 can perform actions to configure hardware components of the compute blade 320 even when the operating system of the compute blade is unresponsive, or one or more components of the compute blade are powered off. In some embodiments, the BMC 326 communicates using the intelligent platform management interface (IPMI), Redfish® communications, custom or other proprietary communications standards. In alternative embodiments, the BMC 326 communicates using other server rack management interfaces. The BMC 326 can collect or manage hardware component configurations and/or parameters such as temperatures, fan speeds, voltage levels, and power consumption. The BMC 326 may also provide functionality such as power cycling, rebooting, or remote access of the compute blade 320. As illustrated, the BMC 326 is connected to a single module which has a single computing component (e.g., GPU 322). It can be appreciated that the module 321 can include multiple computing components (e.g., additional GPUs, etc.), and similarly, the compute blade may include additional modules that are similarly connected to the BMC 326. In some embodiments, a server rack 302 includes multiple compute blades 320, and a single BMC 326 may connect to several compute blades 320. For example, if the server rack 302 includes sixteen compute blades 320, the server rack 302 may include four BMCs 326 that each connect to four compute blades 320, thus connecting the sixteen compute blades 320 to a respective BMC 326.

In some embodiments, and as illustrated, the compute blade 320 can be connected to the low-latency connection 304 via the CAN PHY 327. In some embodiments, the CAN PHY 327 is integrated with the BMC 326. In some embodiments, the CAN PHY 327 is integrated with the computing component, such as GPU 322 (not illustrated).

The switch blade 330 can include memory 331, memory 332, an FPGA 335, BMC 336, CAN PHY 337, an ADC 338, and leak detectors 339.

The memory 331 and the memory 332 can be used to store networking tables (e.g., switching tables, routing tables, etc.) for networking elements in the server rack 302.

The FPGA 335 can perform the same or similar functions as the FPGA 325 of the compute blade 320, described above. Similarly, the BMC 336, CAN PHY 337, ADC 338, and leak detectors 339 can perform the same or similar functions as the BMC 326, CAN PHY 327, ADC 328, and leak detectors 329 also described above with reference to the compute blade 320.

In some embodiments, the switch blade 330 can include one or more processing units (not illustrated). In such embodiments, the power delivered to the processing units can be controlled by the rack power manager 311 via the BMC 336 and/or the CAN PHY 337.

The leak pan 340 includes leak detectors 341, which are connected to a microcontroller unit (MCU) 342. The leak detectors 341 can function the same as the leak detectors 329 or leak detectors 339, described above. The leak detectors 341 can provide a measured signal (e.g., an analog signal) to the MCU 342. The MCU 342 can convert the analog signal to a digital signal and provide the digitized leak signal to the rack management controller 310 via the low-latency connection 304. In some embodiments, the leak pan 340 can be physically located in the server rack 302 in a place that is more likely to accumulate liquids or moisture (e.g., the bottom of the server rack 302), above sensitive components of the server rack 302, and/or below common places of coolant failure.

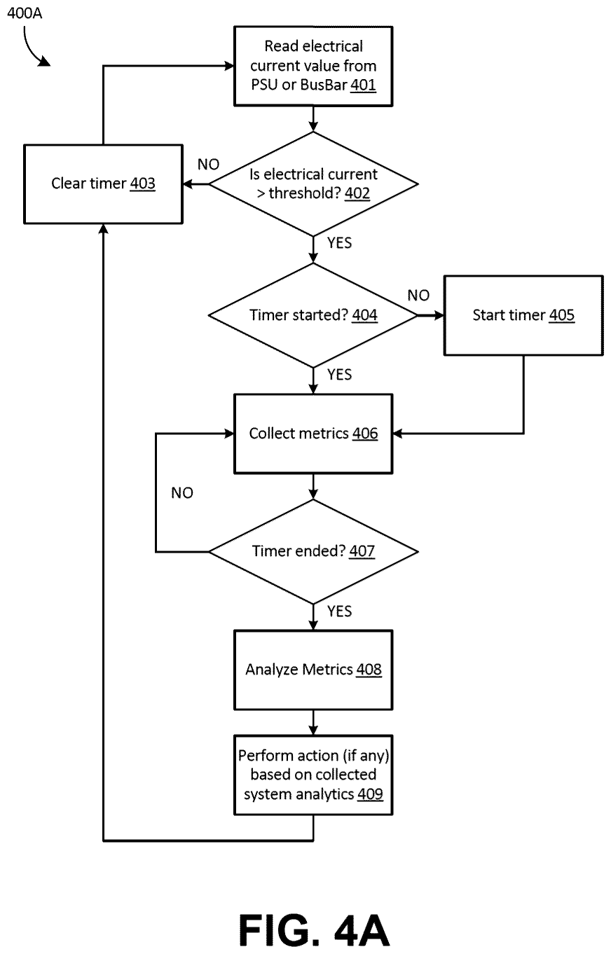

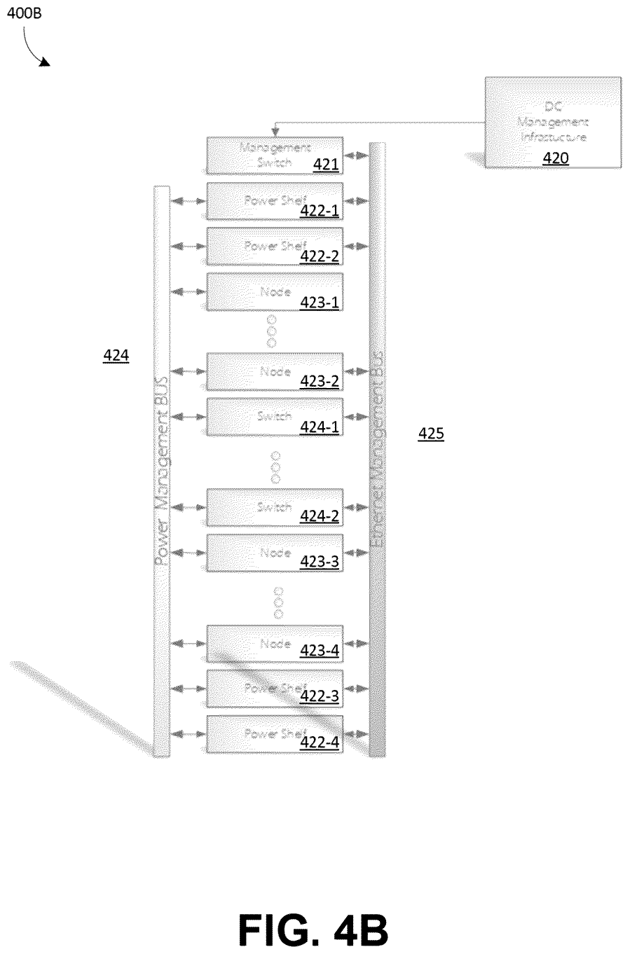

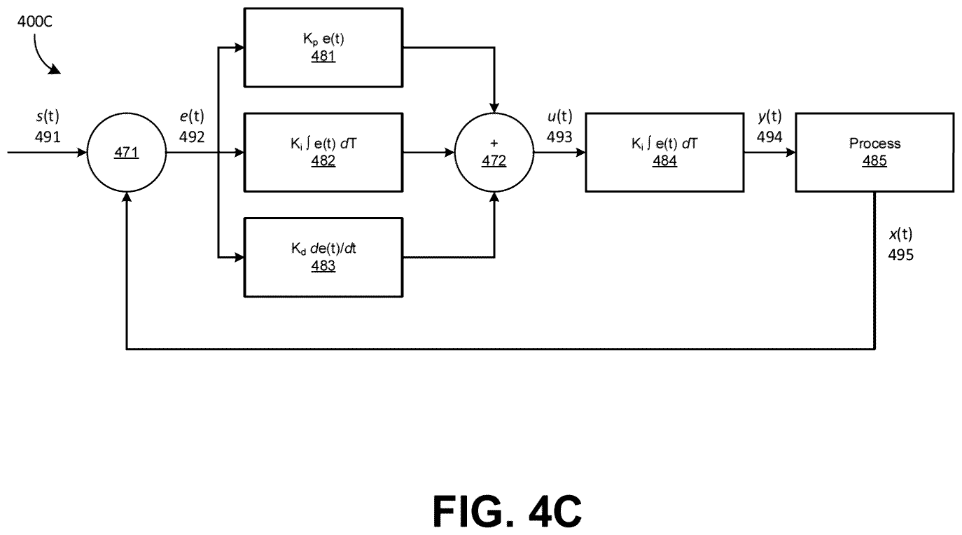

The power shelf 350 includes a power supply unit (PSU) 351 and a PSU 352. In some embodiments, the PSU 351 is a primary power supply, and the PSU 352 is a secondary power supply in case the PSU 351 experiences a failure (or vice-versa). In alternative embodiments, the PSU 351 provides a portion of the power to the server rack 302 and the PSU 352 provides another portion of power to the server rack 302. The PSU 351 and PSU 352 are connected to the power supply controller (PSC) 353, which includes a controller 354. In some embodiments, the controller 354 is an application specific integrated circuit (A SIC). In some embodiments, the controller 354 is a general-purpose micro controller. The PSC 353 uses the controller 354 to monitor the PSU 351 and the PSU 352, and calculates rack power consumption based on the electrical current flow through each PSU. In some embodiments, if the power consumption is determined to be above a predetermined threshold, the controller 354 asserts a power brake to disconnect the PSU 351 and PSU 352 from the other components of the server rack 302. In some embodiments, the power brake disconnects the PSU 351 and PSU 352 from an external power source. FIG. 4A, described below, illustrates a flow chart for a method to monitor the PSU 351 and the PSU 352.

In some embodiments, the PSC 353 can communicate with the rack power manager 311 to provide input power values (e.g., voltage, electrical current, phase, or power levels of input power signals to the PSUs in the power shelf 350). In some embodiments, the PSC 353 can communicate with the rack power manager 311 to provide PSU output power values (e.g., voltage, electrical current, or power levels of output power from the PSUs). In some embodiments, when a compute system has its own PSU, it can implement the same type of logic described herein within the compute system. An external entity (e.g., the power shelf controller) can still allocate maximum and/or minimum power budgets to each compute system. In some embodiments, each compute system manages allocated power independently.

FIG. 3B illustrates an example power shelf 350-1, according to some aspects of the disclosure. The power shelf 350-1 includes the PSUs 351, 352, which are each connected to the PSC 353, which includes the controller 354, as described above with reference to FIG. 3A. In some embodiments, the power shelf 350-1 includes one or more ports, such as a gigabit ethernet port (e.g., GB E 361-1, 361-2), a low-latency connection port (e.g., CAN 362), and a synchronization port (e.g., SYNC 363).

In some embodiments, PSUs 351, 352 are connected to the PSC 353 respectively by multiple connections 355. Illustratively, PSU 351 is connected to the PSC 353 by three connections, power management bus (PMBus) 355-1, general-purpose input/output (GPIO) 355-2, and CAN 355-3. The GPIO 355-2 represents physical connections of the power shelf 350-1. The PMBus 355-1 can route signals indicating how much power should be provided by each PSU to the PSC. In some embodiments, the values of data signals transmitted via the PMBus 355-1 are based on messages received from the rack management controller 310. In some embodiments, the GPIO 355-2 can transmit feedback or other signals to the PSC 353. In some embodiments, the CAN 355-3 can transmit a message from the PSC 353 to the PSU 351, based on a message received from the CAN port 362.

In some embodiments, the controller 354 receives low-latency information from the PSUs 351, 352. In some embodiments, this information is provided via the low-latency connection 304 of FIG. 3A. In some embodiments, the current is an analog value, and an analog-to-digital converter (ADC) can convert the current from the analog value to a digital value prior to providing the value to the low-latency connection 304. In some embodiments, the GPIO 355-2 can be used to indicate a state of the PSUs 351,352, which states can be used to determine an overall available power in a rack. Examples of GPIO values or states are alternating current (AC) on (ACOn), ACPowerLoss, PSU Present, error status, etc.) The PMBUS 355-1 can provide configuration information that can be queried. For example, a current PSU configuration (e.g., a number of active phases). In some embodiments, the role of the PMBUS 355-1 can be satisfied by the low-latency connection 304.

The design of this power shelf 350 within the context of the example system 300A allows for redundancy when losing a single feed. This is in contrast with 2N systems which may be sized sized at 50% of the total available power to provide consistent power. That is, in 2N systems, twice the number of power supplies may be provisioned for redundancy purposes, with the total maximum power limited to N number of power supplies. With a rack level CAN 362 (e.g., low-latency connection 304) as described herein, the power shelf 350 can be run at nearly 100% utilization and throttle back the GPU loads on detections of a loss or dip in AC power. In some embodiments, in the event that either PSU 351 or PSU 352 loses power, a CAN message can trigger a GPU throttle event to set the power shelf 350 power to 50% of a last agreed upon power budget. In some embodiments, the number of PSUs required for redundancy can be reduced. When the number of PSUs drop below a physical redundancy limit (e.g., a predefined limitation based on one or more of datacenter requirements, system requirements, client/customer requirements, etc.), the controller can reduce the overall system power to match what can be delivered by the PSU(s). For example if a system has six PSUs but requires four PSUs to run at maximum performance, a drop to three PSUs is proportional to the number of PSUs left (e.g., three PSUs), and represents a drop of 25% vs a drop of 50% in power (e.g., 3/4 PSUs are in use vs 3/6 PSUs are in use). This prevents a complete loss of power to some or all of the system 300A, merely a potential reduction in performance. In some embodiments, the potential reduction in performance is relative to the reduction in power. That is, in some embodiments, if power is reduced by 50%, performance may similarly be reduced by 50%. An added benefit of the design of this power shelf 350 is a reduction in the number of power shelves 350, and related components, such as AC power whips, tapboxes, and the like, which are needed to maintain a 2N redundancy architecture. In some embodiments, a 2N redundancy architecture can be maintained while increasing available power to the GPUs by a value that depends on the available number of power supplies plus any potential headroom. That is, depending on how many PSUs or AC feeds are loss, it may be possible to maintain a higher power throughput by dynamically allocating power resources without loss of computing resources for the full rack.

FIG. 3C illustrate an example signal diagram 300C for systems that experience power-loss events.

As illustrated, AC feed A 371 and AC feed B 372 are providing power to a rack, shown as available power 373. At time T1 374, AC feed B 372 stops providing power. The power loss is detected at time T2 375, and by time T3 376, the GPU power is throttled in time before the PSU holdup power cuts out. As illustrated, a 50% reduction in AC power (e.g., due to the failure of AC feed B 372) results in a 50% reduction in available power from 66 KW of provided power to 33 kW of provided power, which satisfies the original power requirement of 33 kW.

FIG. 3D illustrates an example signal diagram 300D for systems that experience power-loss events in a proportional power delivery system, according to some aspects of the disclosure.

As illustrated, a PSU failure signal 381 is transmitted, which causes an interrupt on the CAN Bus heartbeat signal 382 at time T1 384. Because of the relatively high duty cycle of the CAN Bus heartbeat signal 382, by the time T2 385, the PSU failure has been reported, and unused power from a non-failing PSU can be delivered. This “pooling” of PSUs is possible using the low-latency connection 304 between the rack management controller 310 and multiple PSUs (e.g., PSUs 351, 352) of a system rack. The low-latency connection 304 allows for the failure to be detected, and other power resources (e.g., from functioning PSUs) to be made available in the time before the power loss from the failed PSU is experienced by a component to which the failed PSU was providing power (e.g., at the time T3 386).

FIG. 4A is a flow diagram of an example method 400A for proportional power control of systems within a server rack, according to some aspects of the disclosure. The method 400A can be performed by control logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400A is performed by the network device 104, 112 of FIG. 1. In some embodiments, the method 400A is performed in whole or in part by the PSC 353 of the system 300A of FIG. 3A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

The method 400A can be managed by a BMC in a server rack, or by a rack management controller. For example, the method 400A can be performed in response to receiving a message from the data management service 301 of FIG. 3A at the PSC 353 (e.g., an automated, manual, or semi-automated message sent by a network administrator). In another example, the method 400A can be performed in response to receiving a message from the rack power manager 311 of the rack management controller 310 of FIG. 3A.

At operation 401, the control logic performing the method 400A reads an electrical current value from a PSU or BusBar.

At operation 402, the control logic determines whether the electrical current value is greater than a predetermined threshold. In response to determining that the overcurrent value is not greater than the predetermined threshold, the control logic proceeds to operation 403, where a system time is cleared. In response to determining that the overcurrent value is greater than the predetermined threshold, the control logic proceeds to operation 404, where a system timer status is checked.

At operation 403, responsive to determining that the overcurrent value is not greater than the predetermined threshold, the control logic clears the value of the system timer. That is, the system timer value is reset to a default value (e.g., “0”). The control logic then returns to the operation 401.

At operation 404, responsive to determining that the overcurrent value is greater than the predetermined threshold, the control logic determines whether the system timer has been started. In response to determining that the system timer has not been started, the control logic proceeds to operation 405, where the system timer is started. In response to determining that the system timer has already been started, the control logic proceeds to operation 406.

At operation 405, responsive to determining that the system timer has not already been started, the control logic proceeds starts the system timer, and proceeds to operation 406.

At operation 406, responsive to determining that the system timer has already been started at the operation 404, or responsive to starting the system time at the operation 405, the control logic collects system metrics.

At operation 407, the control logic determines whether the system timer has ended. Responsive to determining the system timer has ended, the control logic proceeds to operation 408. Responsive to determining the system timer has not ended, the control logic proceeds to operation 406.

At operation 408, responsive to determining the system timer has ended, the processing logic analyzes the collected system metrics.

At operation 409, the control logic performs an action based on the collected system analytics. In some embodiments, no action is performed.

FIG. 4B is an example diagram of a rack architecture 400B in which the method 400A can be performed, according to some aspects of the disclosure.

Rack architecture 400B includes a management switch 421 that is connected to datacenter management infrastructure 420. The management switch 421 can communicate with other compute elements in the rack (e.g., of the rack architecture 400B) via the ethernet management bus 425. In some embodiments, the management switch 421 relays messages from the data center management infrastructure (e.g., from a data center controller) to one or more elements in the rack architecture 400B via the ethernet management bus 425.

The rack architecture 400B further includes power shelves 422-1, 422-2, 422-3, 422-4 which provide power to nodes 423-1, 423-2, 423-3, 423-4 and switches 424-1, 424-2. In some embodiments, the amount of power provided to each of the nodes 423-1, 423-2, 423-3, 423-4 and switches 424-1, 424-2 can be controlled via the power management bus 424.

FIG. 4C is a flow diagram of a process 400C performed by a controller to provide proportional power control of systems within a server rack, according to some aspects of the disclosure. The process 400C can be performed by control logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, the process 400C is performed by a proportional-integral-derivative (PID) controller, or the rack management controller 310 of FIG. 3A. In some embodiments, the process 400C is performed in whole or in part by the PSC 353 of the system 300A of FIG. 3A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

Signal s(t) 491 is received at node 471. The node 471 also receives the output of the feedback loop, signal x(t) 495. Node 471 combines signal s(t) 491 and signal y(t) 494 into signal e(t) 492, which is provided to transformers 481, 482, 483. Each of the transformers performs a respective operation on the signal e(t) 492, and the results of each transformation are summed at the node 472 into the signal u(t) 493. The signal u(t) is provided to the transformer 484, which performs one or more operations to generate the signal y(t) 494. The signal y(t) 494 is provided to the transformer 485 which performs one or more operations to generate the signal x(t) 495. As described above, the signal x(t) 495 is used in a feedback loop as an input to the node 471 to generate the signal e(t) 492.

In some embodiments, each of the transformers 481, 482, 483, 484, 485 can be a separate controller (e.g., separate PID controller). In some embodiments, a single controller, such as the rack management controller 310 performs each of the operations described and illustrated with reference to FIG. 4C. The value of the signal u(t) 493 can be mathematically expressed as:

$$u ( t ) = {K}_{p} e ( t ) + {K}_{i} {\int }_{0}^{t} e ( τ ) d τ + {K}_{d} \frac{de ( t )}{dt}$$

where Kₚ Kᵢ, K_{d} are tuned values to obtain different response behaviors in the PID control loop,
where e(t) is is the delta between the target s(t) and the measured value of the system, and and where

The signal s(t) 491 can be a manufacturing monitoring signal that is obtained from PSUs such as PSU 351, 352 of FIG. 3A-3B that indicates a real-time operational status of the respective PSU. In some embodiments, the signal s(t) 491 is a binary signal. That is, the signal s(t) indicates whether the respective PSU is providing power or not. In alternative embodiments, the signal s(t) 491 can be an analog or digital signal that indicates a level of power provided by the respective PSU. In some embodiments, the level of power is indicated as a percentage of maximum rated power for the PSU, as a power value (e.g., in watts or kilowatts, etc.), as a voltage value, or an electrical current value. In some embodiments, the signal s(t) 491 is an iSENSE™ value.

In some embodiments, any of the signals s(t) 491, e(t) 492, u(t) 493, y(t) 494, or x(t) 495 can be used by the PSU or rack power controller to perform operations to increase or decrease the power supplied to one or more compute devices of the server racks in a datacenter.

The controller performing the process 400C can monitor the signal s(t) 491 and determine based on the the current number of PSUs in a rack, the rack power consumption. If the power consumption exceeds a predetermined threshold, a controller can proportionally reduce the power provided to components of the server rack.

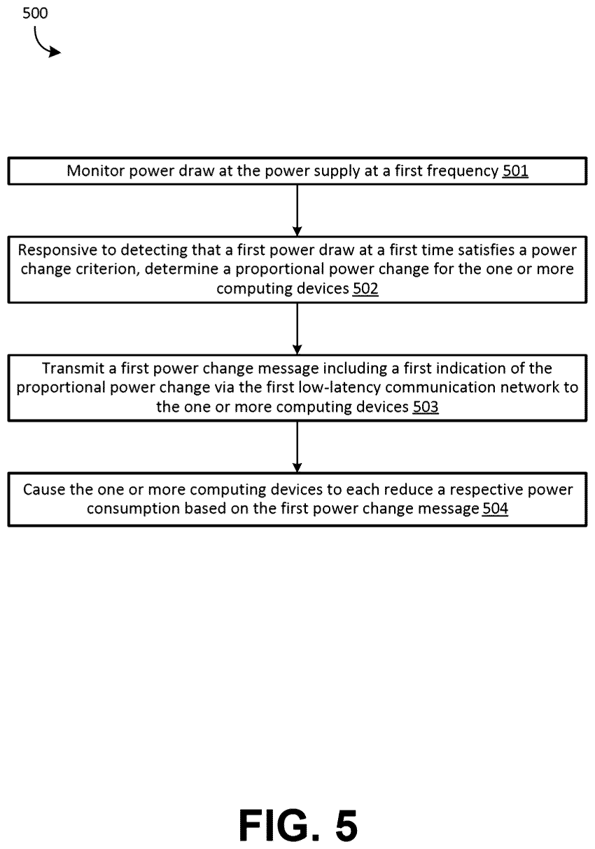

FIG. 5 is a flow diagram of an example method 500 for proportional power control of systems within a server rack, according to some aspects of the disclosure. The method 500 can be performed by control logic that may include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by the network device 104, 112 of FIG. 1. In some embodiments, the method 500 is performed in whole or in part by the rack power manager 311 of the system 300A of FIG. 3A. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 501, the control logic performing the method 500 monitors power draw at a power supply at a first frequency. The first frequency can be a predetermined frequency. For example, and in some embodiments, the first frequency can correspond to a time interval of approximately 1-20 milliseconds. In some embodiments, the frequency is configurable via data center management services 301 as described with reference to FIG. 3A. In some embodiments, the power draw can be monitored at a second frequency that is different from the first frequency in order to collect different information. For example, the control logic may collect electrical current data at a first frequency, alternating current (AC) phase data at a second frequency, and total power input at a third frequency. In some embodiments, the control logic monitors a power draw of the server rack at a first frequency. In some embodiments, the power draw of the server rack is based on an electrical current draw across the server rack and a steady input voltage.

At operation 502, responsive to detecting that a first power draw at a first time satisfies a power change criterion, the control logic determines a proportional power change for one or more computing devices. For example, the proportional power change can be a decrease of 10%, an increase of 10%, a change to 80% of maximum capacity, or the like. In some embodiments, the power change criterion is based on one or more of a change in electrical current, AC phase, total power, voltage, etc.

At operation 503, the control logic transmits a first power change message including the first indication of the proportional power change via the first low-latency communication network to the one or more computing devices. In some embodiments, the first low-latency communication network is a CAN bus.

At operation 504, the control logic causes the one or more computing devices to each reduce a respective power consumption based on the first power change message. In some embodiments, the message indicating the proportional power change is received at the computing device which interprets and converts the message into a set of instructions that are readable by a computing component (e.g., a CPU, GPU, DPU, etc.). These set of instructions cause hardware of the one or more computing components to reduce respective power consumption based on the first power change message. In alternative embodiments, the message indicating the proportional power change is received directly at the computing component (e.g., as a set of instructions that are readable by the computing component). In such embodiments, the computing component can include a physical low-latency communication port. In some embodiments, the message can be a set of power modification instructions that are sent via the low-latency communication network to each computing component. The set of power modification instructions can cause the receiving computing component to proportionally reduce a respective power consumption.

In some embodiments, the control logic can monitor an output power from the power supply at the first frequency. Responsive to determining that the first output power at the first time exceeds the first power draw at the first time, the control logic can transmit the first power change message via the first low-latency communication network.

In some embodiments, the control logic can monitor a power consumption of each computing device. Responsive to detecting that a first power consumption of a first computing device satisfies a power consumption criterion, the control logic can determine a proportional component power change for the computing device. The control logic can cause the power delivery controller to transmit a second power change message via the first low-latency communication network to the first computing device, and cause the one or more computing devices to each reduce the respective power consumption based on the second power change message.

In some embodiments, the second low-latency communication network is used to collect telemetry data. In some embodiments, a telemetry collection controller can connect to the second low-latency communication network to collect the telemetry data. The telemetry collection controller can be configured to monitor and collect the telemetry data. In some embodiments, the telemetry data includes one or more of power consumption data, clock speeds, workload progress, utilization metrics, temperatures, or the like pertaining to a computing device. As used herein, “utilization metric” can refer to a processing capability (e.g., speed, bandwidth, etc. related to a total data-throughput) for a computing device. In some embodiments, the same low-latency communication network is used to send power change messages and collect telemetry data. In an alternative embodiment, the second low-latency communication network can be a low-latency network based on Ethernet protocols.

In some embodiments, the first power change message can be sent to multiple computing devices of a server rack. However, the first power change message may be directed to one or a group of computing devices. Only the devices to which the first power change messages is directed will perform the actions in the first power change message. In alternative embodiments, if the first power change message is directed to a specific computing device, only the specified computing device receives the first power change message. In some embodiments, a second power change message can be sent (under the same conditions and by the same means as the first power change message). The second power change message can be directed to another computing device or component. That is, two computing components in a server rack can receive different power change messages. For example, one GPU may receive a power change message to reduce power consumption to 90%, while at the same time, another GPU may receive a power change message to reduce power consumption to 80%.

### Computer Systems

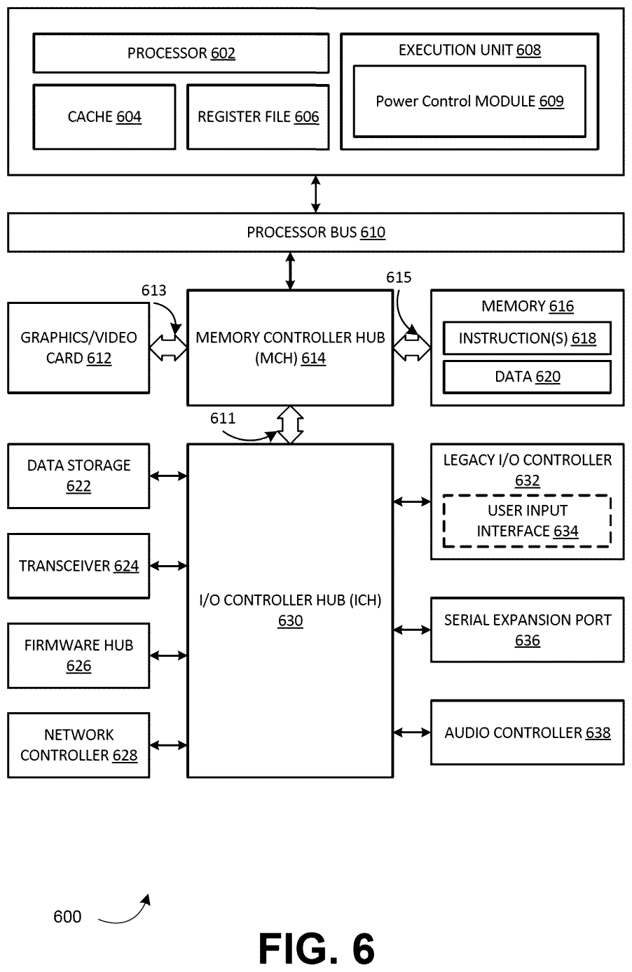

FIG. 6 is a block diagram illustrating an exemplary computer system, such as computer system 600, which can be a system with interconnected devices and components, a system-on-a-chip (SOC), or some combination thereof, according to some aspects of the disclosure. In some embodiments, computer system 600 can include, without limitation, a component, such as a processor 602, to employ execution units including logic to perform algorithms for process data, in accordance with the present disclosure, such as in the embodiments described herein. In some embodiments, computer system 600 can include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) can also be used. In some embodiments, computer system 600 can execute a version of WINDOWS' operating system available from Microsoft Corporation of Redmond, Wash., although other operating systems (UNIX and Linux, for example), embedded software, and/or graphical user interfaces, can also be used.

Embodiments can be used in other devices such as handheld devices and embedded applications. Some examples of handheld devices include cellular phones, Internet Protocol devices, digital cameras, personal digital assistants (PDAs), and handheld PCs. In some embodiments, embedded applications can include a microcontroller, a digital signal processor (DSP), a system on a chip, network computers (NetPCs), set-top boxes, network hubs, wide area network (WAN) switches, or any other system that can perform one or more instructions in accordance with at least one embodiment.

In some embodiments, computer system 600 can include, without limitation, processor 602 that can include, without limitation, one or more execution units 608 to perform operations according to techniques described herein. In some embodiments, computer system 600 is a single-processor desktop or server system, but in another embodiment, the computer system 600 can be a multiprocessor system. In some embodiments, processor 602 can include, without limitation, a complex instruction set computer (CISC) microprocessor, a reduced instruction set computing (RISC) microprocessor, a very long instruction word (VLIW) microprocessor, a processor implementing a combination of instruction sets, or any other processor device, such as a digital signal processor, for example. In some embodiments, processor 602 can be coupled to a processor bus 610 that can transmit data signals between processor 602 and other components in computer system 600.

In some embodiments, processor 602 can include, without limitation, a Level-1 (L1) internal cache memory (cache) cache 604. In some embodiments, processor 602 can have a single internal cache or multiple levels of internal cache. In some embodiments, the cache memory can reside external to processor 602. Other embodiments can also include a combination of both internal and external caches depending on particular implementation and needs. In some embodiments, register file 606 can store different types of data in various registers, including and without limitation, integer registers, floating-point registers, status registers, and instruction pointer registers.

In some embodiments, an execution unit 608, including and without limitation, logic to perform integer and floating-point operations, also reside in processor 602. In some embodiments, processor 602 can also include a microcode (ucode) read-only memory (ROM) that stores microcode for certain macro instructions. In some embodiments, execution unit 608 can include logic to handle a power control module 609. In some embodiments, by including power control module 609 in an instruction set of a general-purpose processor, such as processor 602, along with associated circuitry to execute instructions, operations used by many multimedia applications can be performed using packed data in a general-purpose processor, such as processor 602. In one or more embodiments, many multimedia applications can be accelerated and executed more efficiently by using the full width of a processor's data bus for performing operations on packed data, which can eliminate the need to transfer smaller units of data across the processor's data bus to perform one or more operations one data element at a time.

In some embodiments, execution unit 608 can also be used in microcontrollers, embedded processors, graphics devices, DSPs, and other types of logic circuits. In some embodiments, computer system 600 can include, without limitation, a memory 616. In some embodiments, memory 616 can be implemented as a Dynamic Random Access Memory (DRAM) device, a Static Random Access Memory (SRAM) device, a flash memory device, or other memory devices. In some embodiments, memory 616 can store instruction(s) 618 and/or data 620 represented by data signals that can be executed by processor 602.

In some embodiments, the system logic chip can be coupled to processor bus 610 and memory 616. In some embodiments, the system logic chip can include, without limitation, a memory controller hub (MCH), such as MCH 614, and processor 602 can communicate with MCH 614 via processor bus 610. In some embodiments, MCH 614 can provide a high bandwidth memory path 615 to memory 616 for instruction and data storage and for storage of graphics commands, data, and textures. In some embodiments, MCH 614 can direct data signals between processor 602, memory 616, and other components in computer system 600 and bridge data signals between processor bus 610, memory 616, and a system input/output (I/O) 611. In some embodiments, a system logic chip can provide a graphics port for coupling to a graphics controller. In some embodiments, MCH 614 can be coupled to memory 616 through a high bandwidth memory path 615, and graphics/video card 612 can be coupled to MCH 614 through an Accelerated Graphics Port (AGP) interconnect 613.

In some embodiments, computer system 600 can use the system I/O 611 that is a proprietary hub interface bus to couple the MCH 614 to I/O controller hub (ICH), such as ICH 630. In some embodiments, ICH 630 can provide direct connections to some I/O devices via a local I/O bus. In some embodiments, a local I/O bus can include, without limitation, a high-speed I/O bus for connecting peripherals to memory 616, chipset, and processor 602. Examples can include, without limitation, data storage 622, a transceiver 624, a firmware hub (flash Basic Input/Output System (BIOS)) 626, a network controller 628, a legacy I/O controller 632 containing a user input interface 634, a serial expansion port 636, such as Universal Serial Bus (USB), and an audio controller 638. In some embodiments, data storage 622 can include a hard disk drive, a floppy disk drive, a compact disc read-only memory (CD-ROM) device, a flash memory device, or other mass storage devices.

In some embodiments, FIG. 6 illustrates a computer system 600, which includes interconnected hardware devices or “chips,” whereas, in other embodiments, FIG. 6 can illustrate an exemplary System on a Chip (SoC). In some embodiments, devices can be interconnected with proprietary interconnects, standardized interconnects (e.g., Peripheral Component Interconnect buses (e.g., PCI, PCI Express)), or some combination thereof. In some embodiments, one or more components of computer system 600 are interconnected using compute express link (CXL) interconnects.

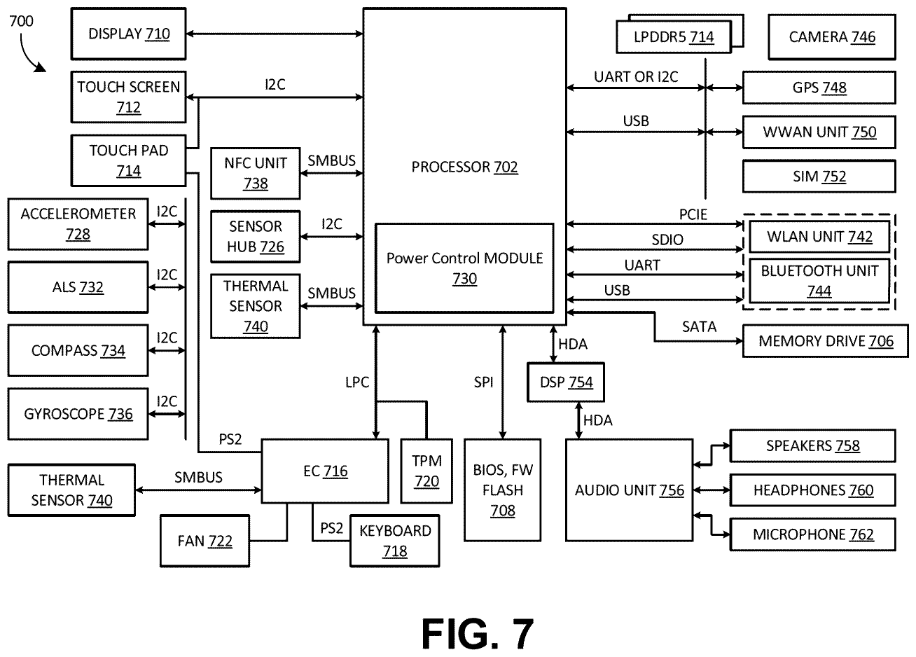

FIG. 7 is a block diagram illustrating an electronic device 700 for utilizing a processor 702, according to some aspects of the disclosure. In some embodiments, electronic device 700 can be, for example, and without limitation, a notebook, a tower server, a rack server, a blade server, a laptop, a desktop, a tablet, a mobile device, a phone, an embedded computer, or any other suitable electronic device.

In some embodiments, electronic device 700 can include, without limitation, processor 702 communicatively coupled to any suitable number or kind of components, peripherals, modules, or devices. In some embodiments, processor 702 coupled using a bus or interface, such as an Inter-Integrated Circuit (I2C) bus, a System Management Bus (SM Bus), a Low Pin Count (LPC) bus, a Serial Peripheral Interface (SPI), a High Definition Audio (HDA) bus, a Serial Advance Technology Attachment (SATA) bus, a Universal Serial Bus (USB) (including USB 1.0/1/1, USB 2.0, USB 3.0/3.1 Gen1/3.1 Gen2, and USB 4), or a Universal Asynchronous Receiver/Transmitter (UART) bus. In some embodiments, FIG. 7 illustrates a system, which includes interconnected hardware devices or “chips,” whereas in other embodiments, FIG. 7 can illustrate an exemplary System on a Chip (SoC). In some embodiments, devices illustrated in FIG. 7 can be interconnected with proprietary interconnects, standardized interconnects (e.g., PCIe), or some combination thereof. In some embodiments, one or more components of FIG. 7 are interconnected using compute express link (CXL) interconnects.

In some embodiments, FIG. 7 can include a display 710, a touch screen 712, a touch pad 714, a Near Field Communications unit (NFC) 738, a sensor hub 726, a thermal sensor 740, an Express Chipset (EC), such as EC 716, a Trusted Platform Module (TPM), such as TPM 720, BIOS/firmware (FW)/flash memory, such as BIOS, FW Flash 708, a DSP 754, a memory drive 706 such as a Solid State Disk (SSD) or a Hard Disk Drive (HDD), a wireless local area network unit (WLAN), such as WLAN unit 742, a Bluetooth unit 744, a Wireless Wide Area Network unit (WWAN), such as WWAN unit 750, a Global Positioning System (GPS) 748, a camera (USB 3.0 camera) 746, such as a USB 3.0 camera, and/or a Low Network bandwidth Double Data Rate (LPDDR) memory unit, such as LPDDR5 704 implemented in, for example, LPDDR5 standard. These components can each be implemented in any suitable manner.

In some embodiments, other components can be communicatively coupled to processor 702 through the components discussed above. In some embodiments, processor 702 can include a power control module 730. In some embodiments, an accelerometer 728, Ambient Light Sensor (ALS), such as ALS 732, compass 734, and a gyroscope 736 can be communicatively coupled to sensor hub 726. In some embodiments, thermal sensor 740, a fan 722, a keyboard 718, and a touch pad 714 can be communicatively coupled to EC 716. In some embodiments, speakers 758, headphones 760, and microphone 762 can be communicatively coupled to an audio unit 756 which can, in turn, be communicatively coupled to DSP 754. In some embodiments, audio unit 756 can include, for example, and without limitation, an audio coder/decoder (codec) and a class-D amplifier. In some embodiments, a subscriber identification module (SIM) card, such as SIM 752 can be communicatively coupled to WWAN unit 750. In some embodiments, components such as WLAN unit 742 and Bluetooth unit 744, as well as WWAN unit 750 can be implemented in a Next Generation Form Factor (NGFF).

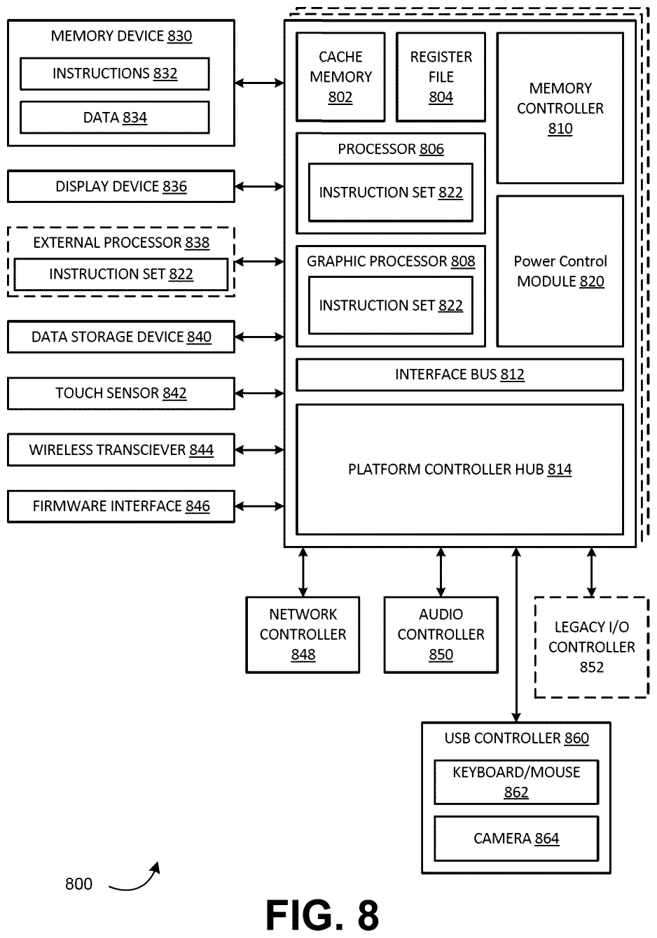

FIG. 8 is a block diagram of a processing system 800, according to some aspects of the disclosure. In some embodiments, the processing system 800 includes cache memory 802, register file 804, processors 806, graphics processors 808, memory controller 810, interface bus 812, platform controller hub 814, and a power control module 820. Processing system 800 can be a single processor desktop system, a multiprocessor workstation system, or a server system having a large number of processors 806 or graphics processors 808. In some embodiments, the processing system 800 is a processing platform incorporated within a system-on-a-chip (SoC) integrated circuit for use in mobile, handheld, or embedded devices.

In some embodiments, the processing system 800 can include, or be incorporated within a server-based gaming platform, a game console, including a game and media console, a mobile gaming console, a handheld game console, or an online game console. In some embodiments, the processing system 800 is a mobile phone, smart phone, tablet computing device, or mobile Internet device. In some embodiments, the processing system 800 can also include, couple with, or be integrated within, a wearable device, such as a smart watch wearable device, smart eyewear device, augmented reality device, or virtual reality device. In some embodiments, the processing system 800 is a television or set-top box device having one or more processors 806 and a graphical interface generated by one or more graphics processors 808.

In some embodiments, one or more processors 806 each include one or more of the processor cores to process instructions which, when executed, perform operations for system and user software. In some embodiments, one or more processors 806 and/or one or more graphics processors can be configured to process a portion of the instruction set 822. In some embodiments, Instruction set 822 can facilitate Complex Instruction Set Computing (CISC), Reduced Instruction Set Computing (RISC), or computing via a Very Long Instruction Word (VLIW). In some embodiments, processor cores can each process a different instruction set from Instruction set 822, which can include instructions to facilitate emulation of other instruction sets (not illustrated). In some embodiments, processor cores can also include other processing devices, such as a Digital Signal Processor (DSP).

In some embodiments, processors 806 includes cache memory 802. In some embodiments, processors 806 can have a single internal cache or multiple levels of internal cache. In some embodiments, cache memory 802 is shared among various components of processors 806. In some embodiments, processors 806 also uses an external cache (e.g., a Level-3 (L3) cache or Last Level Cache (LLC)) (not illustrated), which can be shared among processor cores using known cache coherency techniques. In some embodiments, register file 804 is additionally included in processors 806, which can include different types of registers for storing different types of data (e.g., integer registers, floating-point registers, status registers, and an instruction pointer register). In some embodiments, register file 804 can include general-purpose registers or other registers.

In some embodiments, one or more processors 806 are coupled with one or more interface bus 812 to transmit communication signals such as address, data, or control signals between processor cores and other components in processing system 800. In some embodiments, interface bus 812, in one embodiment, can be a processor bus, such as a version of a Direct Media Interface (DMI) bus. In some embodiments, interface bus 812 is not limited to a DMI bus, and can include one or more peripheral component interconnect (PCI) buses (e.g., PCI, PCI Express), memory busses, or other types of interface busses. In some embodiments, processors 806 include an integrated memory controller (e.g., memory controller 810) and a platform controller hub 814 (PCH). In some embodiments, memory controller 810 facilitates communication between a memory device and other components of the processing system 800, while platform controller hub 814 provides connections to I/O devices via a local I/O bus.

In some embodiments, the memory device 830 can be a dynamic random-access memory (DRAM) device, a static random-access memory (SRAM) device, a flash memory device, a phase-change memory device, or some other memory device having suitable performance to serve as process memory. In some embodiments, the memory device 830 can operate as system memory for processing system 800 to store instructions 832 and data 834 for use when one or more processors 806 executes an application or process. In some embodiments, memory controller 810 also optionally couples with an external processor 838, which can communicate with one or more graphics processors 808 in processors 806 to perform graphics and media operations. In some embodiments, a display device 836 can connect to processors 806. In some embodiments, the display device 836 can include one or more of an internal display device, as in a mobile electronic device or a laptop device, or an external display device attached via a display interface (e.g., DisplayPort, etc.). In some embodiments, display device 836 can include a head-mounted display (HMD) such as a stereoscopic display device for use in virtual reality (VR) applications or augmented reality (AR) applications.

In some embodiments, the platform controller hub 814 enables peripherals to connect to memory device 830 and processors 806 via a high-speed I/O bus. In some embodiments, I/O peripherals include, but are not limited to, a data storage device 840 (e.g., hard disk drive, flash memory, etc.), a touch sensor 842, a wireless transceiver 844, firmware interface 846, a network controller 848, or an audio controller 850.

In some embodiments, the data storage device 840 can connect via a storage interface (e.g., SATA) or via a peripheral bus, such as a PCI bus (e.g., PCI, PCI Express). In some embodiments, touch sensor 842 can include touch screen sensors, pressure sensors, or fingerprint sensors. In some embodiments, wireless transceiver 844 can be a Wi-Fi transceiver, a Bluetooth transceiver, or a mobile network transceiver such as a 3G, 4G, Long Term Evolution (LTE), 5G, or 6G transceiver. In some embodiments, firmware interface 846 enables communication with system firmware and can be, for example, a unified extensible firmware interface (UEFI). In some embodiments, the network controller 848 can enable a network connection to a wired network. In some embodiments, a high-performance network controller (not illustrated) couples with interface bus 812. In some embodiments, audio controller 850 can be a multi-channel high-definition audio controller. In some embodiments, the processing system 800 includes an optional legacy I/O controller 852 for coupling legacy (e.g., Personal System-2 (PS/2)) devices to the processing system 800. In some embodiments, the platform controller hub 814 can also connect to one or more Universal Serial Bus (USB) controllers, such as USB controller 860 to connect input devices, such as a keyboard and mouse combination (keyboard/mouse 862), a camera 864, or other USB input devices.

In some embodiments, an instance of memory controller 810 and platform controller hub 814 can be integrated into a discreet external graphics processor, such as external processor 838. In some embodiments, the platform controller hub 814 and/or memory controller 810 can be external to one or more processors 806. For example, in some embodiments, the processing system 800 can include an external memory controller (e.g., memory controller 810) and the platform controller hub 814, which can be configured as a memory controller hub and peripheral controller hub within a system chipset that is in communication with the processors 806.

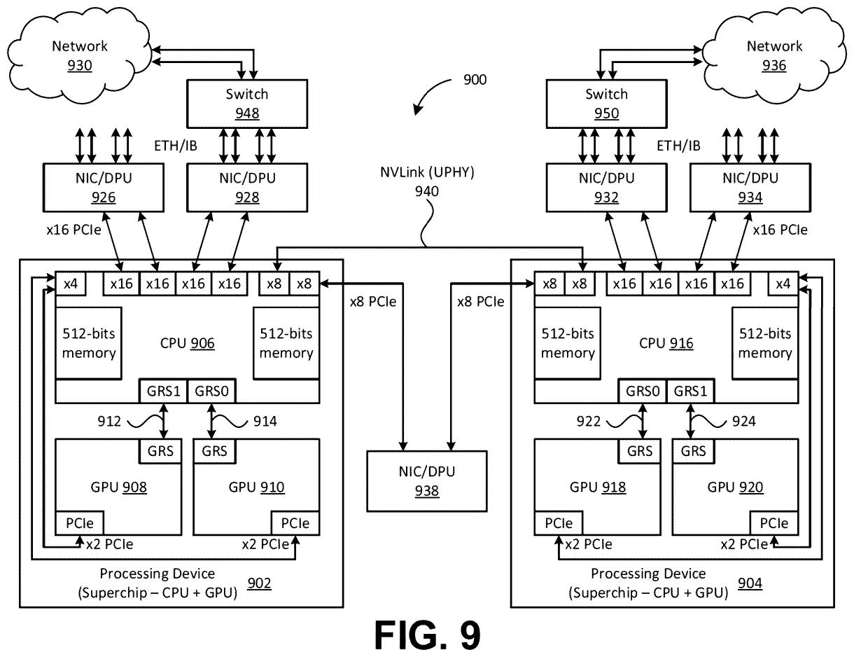

FIG. 9 is a block diagram that schematically illustrates a computing system 900, e.g., a data center or a High-Performance Computing (HPC) cluster, according to some aspects of the disclosure. System 900 comprises a plurality of subsystems, e.g. multiple processing devices coupled to each other, multiple network devices, and multiple networks, according to at least one embodiment. Computing system 900 is designed with multiple integrated circuits (referred to as processing devices), where each integrated circuit can include one or more CPUs and GPUs, forming a powerful and flexible architecture.

The various processing devices are interconnected via an NVLINK or other high-speed interconnect, enabling high-speed communication between the subsystems, and are also connected through a NIC or DPU to ensure efficient data transfer across computing system 900 and to one or more external networks 930, 936. In the present example, system 900 comprises a packet switch 948 that connects NIC/DPU 928 to network 930, and a packet switch 950 that connects NIC/DPU 932 to network 936.

The coupling of processing devices through NVLINK allows for seamless data exchange and parallel processing, enhancing overall computational performance. The processing devices are connected to multiple networks through one or more network interface cards (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 900 can include one or more CPUs and one or more GPUs.

FIG. 9 also demonstrates an example architecture of a multi-GPU architecture. As illustrated in the figure, computing system 900 includes a processing device 902 with a multi-GPU architecture. In particular, processing device 902 may be a system-on-chip and includes multiple subsystems such as a CPU 906, a GPU 908, and a GPU 910. CPU 906 can be coupled to GPU 908 via a die-to-die (D2D) or chip-to-chip (C2C) interconnect 912, such as a Ground-Referenced Signaling interconnect (GRS interconnect). CPU 906 can be coupled to GPU 910 via a D2D or C2C interconnect 914. CPU 906 can also couple to GPU 908 and GPU 910 via PCIe interconnects.

CPU 906 can be coupled to one or more NICs or DPUs, which are coupled to one or more networks. For example, as illustrated in FIG. 3A, CPU 906 is coupled to a first NIC/DPU 926, which is coupled to a network 930. CPU 906 is also coupled to a second NIC/DPU 928, which is coupled to network 930 via switch 948. NIC/DPU 926 and NIC/DPU 928 can be coupled to network 930 over Ethernet (ETH), NVLINK or InfiniBand (IB) connections, for example.

Computing system 900 also includes a processing device 904 with a multi-GPU architecture. In particular, processing device 904 includes multiple subsystems including a CPU 916, a GPU 918, and a GPU 920. CPU 916 can be coupled to GPU 918 via an D2D or C2C interconnect 922. CPU 916 can be coupled to GPU 920 via a D2D or C2C interconnect 924. CPU 916 can also couple to GPU 918 and GPU 920 via PCIe interconnects. CPU 916 can be coupled to one or more NICs or DPUs, which are coupled to one or more networks. For example, as illustrated in FIG. 3A, CPU 916 is coupled to a first NIC/DPU 932, which is coupled to a network 936. CPU 916 is also coupled to a second NIC/DPU 934, which is coupled to network 936 via switch 950. NIC/DPU 932 and NIC/DPU 934 can be coupled to network 936 over Ethernet (ETH), NVLINK or InfiniBand (IB) connections.

In at least one embodiment, processing device 902 and processing device 904 can communication with each other via a NIC/DPU 938, such as over PCIe interconnects. Processing device 902 and processing device 904 can also communicate with each other over a high-bandwidth communication interconnects 940, such as an NVLINK interconnect or other high-speed interconnects. The packet switches in FIG. 3A may comprise, for example, Nvidia Quantum-2 switches. The NICs/DPUs in the figure may comprise, for example, Nvidia Bluefield DPUs.

The computing system 900 includes various types of interconnects. Each of the interconnects includes the transceivers or receivers that include the transceiver logic 220 or transceiver logic 240 of FIG. 2, as described herein.

In at least one embodiment, the computing system 900 is used for high-speed network communication and includes a processing unit (e.g., CPU 906, GPU 908, GPU 908, CPU 916, GPU 918, GPU 920, NIC/DPU 926, NIC/DPU 928, NIC/DPU 932, NIC/DPU 934, or NIC/DPU 938), and a network interface coupled to the processing unit. The network interface includes a transceiver circuit operatively coupled to a controller. The transceiver circuit includes an encryption module which is controlled by the controller, as described above. The encryption keys are rotated based on commands received at the encryption module from the controller. The connection between the controller and the encryption module is a local, trusted connection. The communication network that connects the processing device 902 to the processing device 904 does not include a connection to the controller, or otherwise process or send encryption keys.

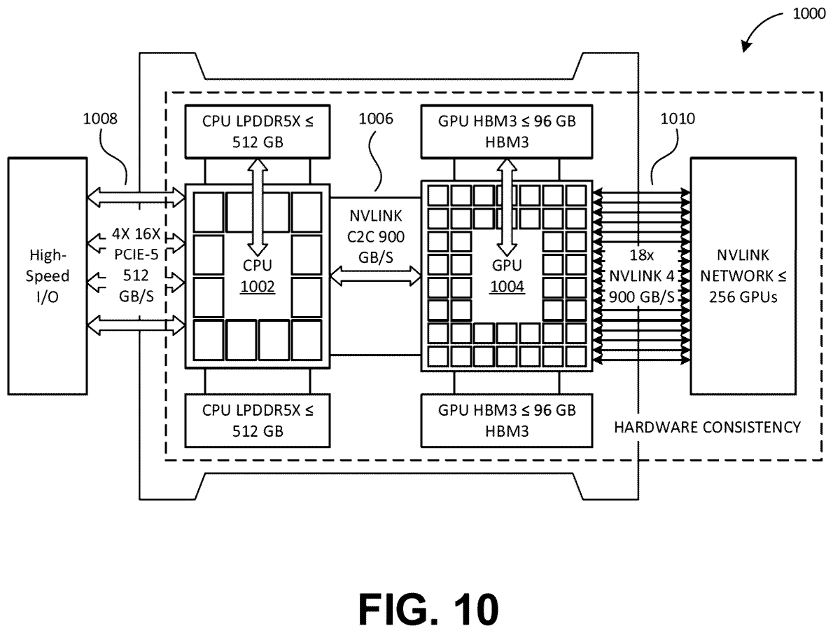

FIG. 10 is a block diagram of a computing system 1000 having a CPU 1002 and a GPU 1004 in a single integrated circuit, according to some aspects of the disclosure. The computing system 1000 can be a highly integrated design where a CPU 1002 and GPU 1004 are connected on a single integrated circuit, utilizing an NVLINK C2C (Chip-to-Chip) interconnect 1006 to enable fast, low-latency communication between the two processing units. This close integration allows for efficient data transfer and parallel processing between the CPU 1002 and GPU 1004, optimizing performance for complex computational tasks. The GPU elements within the computing system 1000 can be interconnected using an NVLINK network, allowing for scalability to include multiple GPU elements (e.g., up to 256 as illustrated), creating a powerful, unified processing environment ideal for large-scale AI, ML, and high-performance computing applications. The NVLINK network can be a GPU fabric of high-bandwidth communication interconnects 1010. Additionally, the computing system 1000 can be designed to interface with a high-speed I/O through PCIe interconnects 1008, ensuring rapid data transfer to and from external devices, further enhancing the system's capabilities in handling data-intensive tasks and providing robust connectivity to peripheral components. It should be noted that the C2C interconnects 1006 can be considered D2D interconnects since the CPU 1002 and the GPU 1004 are located on the same integrated circuit. The integrated circuit can include CPU memory (also referred to as main memory) and GPU memory, which are accessible by the CPU 1002 and the GPU 1004, respectively, over high-speed interconnects. The computing system 1000 can bring together performance of the GPU 1004 with the versatility of the CPU 1002. The CPU 1002 can be connected with a high-bandwidth and memory coherent C2C interconnects 1006 in a single integrated circuit. The computing system 1000 can support a link switch system.

The computing system 1000 includes various types of interconnects. Each of the interconnects includes the transceivers or receivers that include the transceiver logic 220 or transceiver logic 240 of FIG. 2, as described herein.

In at least one embodiment, the computing system 1000 is used for high-speed network communication and includes a processing unit (e.g., CPU 1002, GPU 1004, NVLINK network), and a network interface coupled to the processing unit. The network interface can include the controller as described above with respect to FIG. 10.

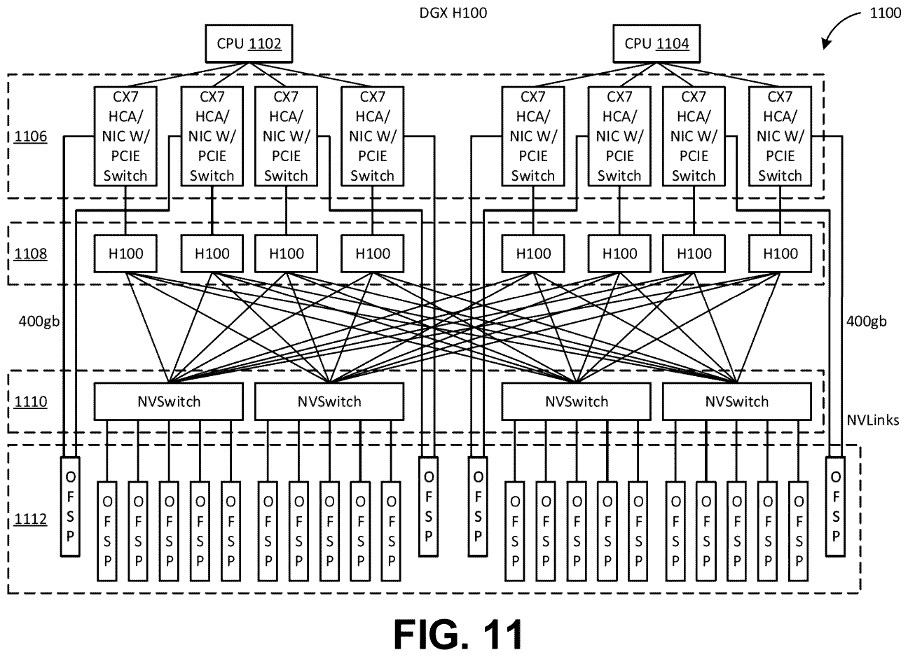

FIG. 11 is a block diagram of a computing system 1100 having tensor core GPUs 1108, according to some aspects of the disclosure. The computing system 1100 can be an NVIDIA© DGX H100 system which is a high-performance computing platform designed to meet the demands of AI, ML, and deep learning (DL) workloads. The computing system 1100 can include multiple tensor core GPUs 1108 (e.g., NVIDIA H100 Tensor Core GPUs). The tensor core GPUs 1108 can each be one of the integrated circuits described above with respect to FIG. 10. The tensor core GPUs 1108 can be optimized for AI/ML/DL applications, offering exceptional performance for deep learning training, inference, and high-performance computing tasks. The tensor core GPUs 1108 within the computing system 1100 are interconnected using high-speed communication interfaces like NVLINKs, enabling rapid data transfer between them, which is crucial for handling large-scale AI models and datasets with low latency. This computing system 1100 is designed for scalability, allowing for the integration of additional GPUs as required, making it versatile enough for research, development, and deployment in data centers for production AI workloads. Each GPU is equipped with Tensor Cores, specialized processing units that accelerate matrix operations, a fundamental component of AI and deep learning algorithms. These Tensor Cores enable the system to perform mixed-precision calculations efficiently, balancing speed and accuracy. Given the power consumption and heat generation of multiple tensor core GPUs 1108, the computing system 1100 can include advanced cooling solutions and power management features to ensure safe operation while maintaining peak performance. It is supported by a comprehensive software ecosystem, including NVIDIA's CUDA programming model, AI frameworks like TensorFlow and PyTorch, and other HPC and AI software tools, which enable developers and researchers to harness the full power of the tensor core GPUs 1108 for their specific applications. The computing system 1100 is ideally suited for large-scale AI model training, real-time inference, scientific simulations, data analytics, and other compute-intensive tasks that require massive parallel processing power.

The tensor core GPUs 1108 can be coupled to multiple CPUs, such as CPU 1102 and GPU 1104, using switches 1106 (e.g., CX7HCA/NIC with PCIe switch). The tensor core GPUs 1108 can be coupled to each other via switches 1110 (e.g., NV Switches). The switches 1106 and switches 1110 can be coupled to high-speed transceiver modules 1112. The high-speed transceiver modules 1112 can be Octal Small Form-factor Pluggable (OSFP) modules. OSFP modules refer to high-speed transceiver modules designed for rapid data communication, particularly in environments requiring significant bandwidth, such as data centers and high-performance computing systems. These modules support extremely high data rates, typically up to 400 Gbps per module, with future capabilities extending to 800 Gbps or more. OSFP modules interface with the system via the PCIe interface, enabling fast and efficient data transfer between the integrated CPU-GPU components and external networks or other connected systems. Their hot-pluggable nature allows for easy insertion or removal without the need to power down the system, offering flexibility and ease of maintenance, which is crucial in critical-uptime environments. Additionally, OSFP modules are designed for high density, maximizing the number of high-speed connections within limited space, such as in densely packed server racks. By adhering to the latest networking standards, OSFP modules ensure the computing system 1100 remains capable of meeting increasing data demands and can be upgraded to support future advancements in network speeds, thus contributing to the system's overall performance and scalability.

In at least one embodiment, the computing system 1100 can be considered a data-network configuration with full-bandwidth intra-server NVLINKs. In this example, all eight tensor core GPUs 1108 can simultaneously saturate eighteen NVLINKs to other GPUs within the server. The bandwidth is limited by over-subscription from multiple other GPUs. In another embodiments, data-network configuration can be a half-bandwidth intra-server NVLINKs. In this example, all eight tensor core GPUs 1108 can half-subscribe eighteen NVLINKs to GPUs in other servers. Four tensor core GPUs 1108 can saturate eighteen NVLINKs to GPUs in other servers. This is equivalent of full-bandwidth on AllReduce with Scalable Hierarchical Aggregation and Reduction Protocol (SHARP). The reduction in all-2-all (All2All) bandwidth is a balance with server complexity and costs. In at least one embodiment, all eight tensor core GPUs 1108 can independently transfer data, using Remote Direct Memory Access (RDMA) protocol, over its own dedicated switch (e.g., 400 A Gb/s HCA/NIC) in an multi-rail InfiniBand/Ethernet configuration. In this example, 800 GBps of aggregate full-duplex to non-NVLINK network devices.

The computing system 1100 includes various types of interconnects. Each of the interconnects includes the transceivers or receivers that include the transceiver logic 220 or transceiver logic 240 of FIG. 2, as described herein.

In at least one embodiment, the computing system 1100 is used for high-speed network communication and includes a processing unit (e.g., CPU 1102, GPU 1104, switches 1106, tensor core GPUs 1108, switches 1110, high-speed transceiver modules 1112), and a network interface coupled to the processing unit. The network interface can the controller as described above with respect to FIG. 10.

Other variations are within the spirit of the present disclosure. Thus, while disclosed techniques are susceptible to various modifications and alternative constructions, certain illustrated embodiments thereof are shown in drawings and have been described above in detail. It should be understood, however, that there is no intention to limit the disclosure to a specific form or forms disclosed, on the contrary, the intention is to cover all modifications, alternative constructions, and equivalents falling within the spirit and scope of the disclosure, as defined in appended claims.

Use of terms “a” and “an” and “the” and similar referents in the context of describing disclosed embodiments (especially in the context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. The term “connected,” when unmodified and referring to physical connections, is to be construed as partly or wholly contained within, attached to, or joined together, even if there is something intervening. Recitations of ranges of values herein are merely intended to serve as a shorthand method of referring individually to each separate value falling within the range, unless otherwise indicated herein, and each separate value is incorporated into the specification as if it were individually recited herein. Use of the term “set” (e.g., “a set of items”) or “subset,” unless otherwise noted or contradicted by context, is to be construed as a nonempty collection comprising one or more members. Further, unless otherwise noted or contradicted by context, the term “subset” of a corresponding set does not necessarily denote a proper subset of the corresponding set, but the subset and corresponding set can be equal.

Conjunctive language, such as phrases of the form “at least one of A, B, and C,” or “at least one of A, B, and C,” unless specifically stated otherwise or otherwise clearly contradicted by context, is otherwise understood with the context as used in general to present that an item, term, etc., can be either A or B or C, or any nonempty subset of a set of A and B and C. For instance, in an illustrative example of a set having three members, conjunctive phrases “at least one of A, B, and C” and “at least one of A, B, and C” refer to any of the following sets: {A}, {B}, {C}, {A, B}, {A, C}, {B, C}, {A, B, C}. Thus, such conjunctive language is not generally intended to imply that certain embodiments require at least one of A, at least one of B, and at least one of C each to be present. In addition, unless otherwise noted or contradicted by context, the term “plurality” indicates a state of being plural (e.g., “a plurality of items” indicates multiple items). A plurality is at least two items but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In some embodiments, a process such as those processes described herein (or variations and/or combinations thereof) is performed under the control of one or more computer systems configured with executable instructions and is implemented as code (e.g., executable instructions, one or more computer programs or one or more applications) executing collectively on one or more processors, by hardware or combinations thereof. In some embodiments, code is stored on a computer-readable storage medium, for example, in form of a computer program comprising a plurality of instructions executable by one or more processors. In some embodiments, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In some embodiments, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause a computer system to perform operations described herein. A set of non-transitory computer-readable storage media, in some embodiments, comprises multiple non-transitory computer-readable storage media and one or more of individual non-transitory storage media of multiple non-transitory computer-readable storage media lacks all of the code while multiple non-transitory computer-readable storage media collectively store all of the code. In some embodiments, executable instructions are executed such that different instructions are executed by different processors—for example, a non-transitory computer-readable storage medium stores instructions, and a main central processing unit (CPU) executes some of the instructions while a graphics processing unit (GPU) executes other instructions. In some embodiments, different components of a computer system have separate processors, and different processors execute different subsets of instructions.

Accordingly, in some embodiments, computer systems are configured to implement one or more services that singly or collectively perform operations of processes described herein, and such computer systems are configured with applicable hardware and/or software that enable the performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples or exemplary language (e.g., “such as”) provided herein is intended merely to better illuminate embodiments of the disclosure and does not pose a limitation on the scope of the disclosure unless otherwise claimed. No language in the specification should be construed as indicating any non-claimed element as essential to the practice of the disclosure.

All references, including publications, patent applications, and patents, cited herein are hereby incorporated by reference to the same extent as if each reference were individually and specifically indicated to be incorporated by reference and were set forth in its entirety herein.

In description and claims, the terms “coupled” and “connected,” along with their derivatives, can be used. It should be understood that these terms cannot be intended as synonyms for each other. Rather, in particular examples, “connected” or “coupled” can be used to indicate that two or more elements are in direct or indirect physical or electrical contact with each other. “Coupled” can also mean that two or more elements are not in direct contact with each other but yet still co-operate or interact with each other.

Unless specifically stated otherwise, it can be appreciated that throughout specification terms such as “processing,” “computing,” “calculating,” “determining,” or like, refer to action and/or processes of a computer or computing system or similar electronic computing device, that manipulates and/or transform data represented as physical, such as electronic, quantities within computing system's registers and/or memories into other data similarly represented as physical quantities within computing system's memories, registers or other such information storage, transmission or display devices.

In a similar manner, the term “processor” can refer to any device or portion of a device that processes electronic data from registers and/or memory and transform that electronic data into other electronic data that can be stored in registers and/or memory. As non-limiting examples, a “processor” can be a CPU or a GPU. A “computing platform” can comprise one or more processors. As used herein, “software” processes can include, for example, software and/or hardware entities that perform work over time, such as tasks, threads, and intelligent agents. Also, each process can refer to multiple processes for carrying out instructions in sequence or in parallel, continuously, or intermittently. The terms “system” and “method” are used herein interchangeably insofar as a system can embody one or more methods, and methods can be considered a system.

In the present document, references can be made to obtaining, acquiring, receiving, or inputting analog or digital data into a subsystem, computer system, or computer-implemented machine. Obtaining, acquiring, receiving, or inputting analog and digital data can be accomplished in a variety of ways, such as by receiving data as a parameter of a function call or a call to an application programming interface. In some implementations, the process of obtaining, acquiring, receiving, or inputting analog or digital data can be accomplished by transferring data via a serial or parallel interface. In another implementation, the process of obtaining, acquiring, receiving, or inputting analog or digital data can be accomplished by transferring data via a computer network from providing entity to acquiring entity. References can also be made to providing, outputting, transmitting, sending, or presenting analog or digital data. In various examples, the process of providing, outputting, transmitting, sending, or presenting analog or digital data can be accomplished by transferring data as an input or output parameter of a function call, a parameter of an application programming interface, or an interprocess communication mechanism.

Although the discussion above sets forth example implementations of described techniques, other architectures can be used to implement described functionality and are intended to be within the scope of this disclosure. Furthermore, although specific distributions of responsibilities are defined above for purposes of discussion, various functions and responsibilities might be distributed and divided in different ways, depending on circumstances.

Furthermore, although the subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system comprising:
a computing node coupled to at least one power supply and comprising one or more computing devices;
a power delivery controller coupled to the at least one power supply; and
a first low-latency communication network coupling the power delivery controller to the one or more computing devices, wherein the power delivery controller is to:
monitor power draw at the at least one power supply at a first frequency;
responsive to detecting that a first power draw at a particular time satisfies a power change criterion, determine a proportional power change for the one or more computing devices;
transmit a first power change message including a first indication of the proportional power change via the first low-latency communication network to the one or more computing devices; and
cause the one or more computing devices to each reduce a respective power consumption based on the first power change message.

2. The system of claim 1, wherein each computing device of the computing node is coupled to a respective power supply of the at least one power supply.

3. The system of claim 1, wherein the one or more computing devices are coupled to the at least one power supply.

4. The system of claim 1, wherein the power delivery controller is further to:
monitor an output power from the at least one power supply at the first frequency; and
responsive to determining that a first output power at the particular time exceeds the first power draw at the particular time, transmit the first power change message via the first low-latency communication network.

5. The system of claim 1, further comprising:
a telemetry collection controller; and
a second low-latency communication network that couples the telemetry collection controller to the one or more computing devices, wherein the telemetry collection controller is to:
monitor a power consumption of each computing device of the one or more computing devices;
responsive to detecting that a first power consumption of a first computing device of the one or more computing devices satisfies a power consumption criterion, determine a proportional component power change for the first computing device;
cause the power delivery controller to transmit a second power change message via the first low-latency communication network to the first computing device; and
cause the one or more computing devices to each reduce the respective power consumption based on the second power change message.

6. The system of claim 5, wherein the first low-latency communication network and the second low-latency communication network are a same low-latency communication network, and wherein the power delivery controller comprises the telemetry collection controller.

7. The system of claim 5, wherein the telemetry collection controller is further configured to monitor a temperature and a utilization of each computing device of the one or more computing devices.

8. The system of claim 1, wherein the one or more computing devices comprise at least one computing component, wherein the first power change message comprises an indication of a proportional component power change for the at least one computing component.

9. The system of claim 8, wherein a first value of the indication of the proportional power change for the one or more computing devices is different from a second value of the indication of the proportional component power change for the at least one computing component.

10. The system of claim 1, wherein the one or more computing devices comprise at least one computing component, wherein the first low-latency communication network is coupled directly to the at least one computing component, wherein the power delivery controller is further to:
transmit, to the at least one computing component via the first low-latency communication network, an instruction to proportionally reduce a respective power consumption.

11. The system of claim 1, wherein to monitor power draw at the power supply at a first frequency, the power delivery controller is to:
monitor electrical current draw at the at least one power supply at the first frequency; and
determine the power draw based on the electrical current draw.

12. A method comprising:
monitoring, by at least one controller, power draw at at least one power supply coupled to one or more computing devices;
responsive to detecting that a first power draw at a particular time satisfies a power change criterion, determining a proportional power change for the one or more computing devices;
transmitting a first power change message including a first indication of the proportional power change via a first low-latency communication network that couples the controller to the one or more computing devices; and
causing the one or more computing devices to reduce at least a power consumption by the one or more computing devices based on the first power change message.

13. The method of claim 12, wherein each computing device of the one or more computing nodes is coupled to a respective power supply of the at least one power supply.

14. The method of claim 12, wherein monitoring the power draw further comprises monitoring electrical current draw at the at least one power supply, and further comprising determining the power draw based on the electrical current draw.

15. The method of claim 12, further comprising:
monitoring an output power from the at least one power supply; and
responsive to determining that a first output power at the particular time exceeds the first power draw at the particular time, transmitting the first power change message via the first low-latency communication network.

16. The method of claim 12, further comprising:
monitoring, by the at least one controller, a power consumption of each computing device of the one or more computing devices;
responsive to detecting that a first power consumption of a first computing device of the one or more computing devices satisfies a power consumption criterion, determining a proportional component power change for the first computing device;
causing the controller to transmit a second power change message via the first low-latency communication network to the first computing device based on the proportional component power change; and
causing the one or more computing devices to each reduce the respective power consumption based on the second power change message.

17. The method of claim 12, wherein the one or more computing devices comprise a computing component, wherein the first power change message comprises an indication of a proportional component power change for the computing component.

18. The method of claim 12, wherein the one or more computing devices comprise a computing component, wherein the first low-latency communication network is coupled directly to the computing component, the method further comprising:
transmitting, to the computing components via the first low-latency communication network, an instruction to proportionally reduce a respective power consumption.

19. A device comprising:
a power delivery controller coupled to a plurality of computing components via a low-latency communication network, wherein the plurality of computing component comprises at least one low-latency communication port, and wherein the power delivery controller is to:
detect a change in current draw for the plurality of computing components; and
responsive to detecting the change in current draw, transmit power modification instructions to at least one of the plurality of computing components via the low-latency communication network, wherein the power modification instructions cause at least one of the plurality of computing components to reduce a power consumption.

20. The device of claim 19, wherein a computing component of the plurality of computing components is at least one of a central processing unit (CPU), a graphics processing unit (GPU), or a data processing unit (DPU).
